(19) United States
(12) Patent Application Publication
(10) Pub. No.: US 2025/0220905 A1
(43) Pub. Date: Jul. 3, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventor: Juhyung KIM, Suwon-si (KR)

(73) Assignee: SAMSUNG ELECTRONICS CO., LTD., Suwon-si (KR)

(21) Appl. No.: 18/974,307

(22) Filed: Dec. 9, 2024

(30) Foreign Application Priority Data
Jan. 2, 2024 (KR) 10-2024-0000495

(51) Int. Cl. H10B 43/27; H10B 43/10; H10B 43/35

(52) U.S. Cl. CPC H10B 43/27; H10B 43/10; H10B 43/35

(57) ABSTRACT

A semiconductor device, including: a plurality of gate lines spaced apart in a vertical direction around a vertical hole; a channel layer extending in the vertical hole; a composite dielectric layer between the plurality of gate lines and the channel layer and comprising a channel-side dielectric layer, a ferroelectric layer, and a boundary dielectric layer sequentially stacked in a direction toward the plurality of gate lines from the channel layer; and a gap-fill insulation pattern between the plurality of gate lines, wherein the boundary dielectric layer comprises a plurality of boundary dielectric patterns spaced apart in the vertical direction and facing the plurality of gate lines, and wherein a first height corresponding to a length of each boundary dielectric pattern in the vertical direction is less than a second height corresponding to a length of each gate line in the vertical direction.

### CROSS-REFERENCE TO RELATED APPLICATION

This application is based on and claims priority under 35 U.S.C. § 119 to Korean Patent Application No. 10-2024-0000495, filed on Jan. 2, 2024, in the Korean Intellectual Property Office, the disclosure of which is incorporated by reference herein in its entirety.

### BACKGROUND

### 1. Field

The present disclosure relates to a semiconductor device and an electronic system including the same.

### 2. Description of Related Art

As semiconductor devices increase in capacity and are highly integrated, vertical semiconductor memory devices have been proposed in which a memory capacity is increased by stacking a plurality of memory cells in a vertical direction on a substrate. However, this reduction in an interval between cells adjacent to each other in a vertical direction may result in a reduction in the reliability of semiconductor devices.

### SUMMARY

Provided is a semiconductor device in which reliability is enhanced.

Also provided is an electronic system including a semiconductor device in which reliability is enhanced.

Additional aspects will be set forth in part in the description which follows and, in part, will be apparent from the description, or may be learned by practice of the presented embodiments.

In accordance with an aspect of the disclosure, a semiconductor device includes: a plurality of gate lines which are spaced apart in a vertical direction, and which are around a vertical hole; a channel layer extending in the vertical hole; a composite dielectric layer disposed between the plurality of gate lines and the channel layer, wherein the composite dielectric layer comprises a channel-side dielectric layer, a ferroelectric layer, and a boundary dielectric layer sequentially stacked in a direction toward the plurality of gate lines from the channel layer; and a gap-fill insulation pattern disposed between the plurality of gate lines, wherein the boundary dielectric layer comprises a plurality of boundary dielectric patterns which are spaced apart in the vertical direction and which face the plurality of gate lines, and wherein a first height corresponding to a length of each boundary dielectric pattern of the plurality of boundary dielectric patterns in the vertical direction is less than a second height corresponding to a length of each gate line of the plurality of gate lines in the vertical direction.

In accordance with an aspect of the disclosure, a semiconductor device includes: a stack structure comprising a plurality of gate lines spaced apart in a vertical direction and overlapping in the vertical direction, and a gap-fill insulation pattern between the plurality of gate lines; a channel layer extending in a vertical hole which passes through the stack structure in the vertical direction; a channel-side dielectric layer on an outer wall of the channel layer; and a plurality of ferroelectric patterns spaced apart in the vertical direction and overlapping in the vertical direction, wherein the gap-fill insulation pattern is between each ferroelectric pattern of the plurality of ferroelectric patterns, and wherein the each ferroelectric pattern is between a corresponding pair of adjacent gate lines from among the plurality of gate lines, wherein a portion of a sidewall of each gate line from among the plurality of gate lines facing the channel layer is on the gap-fill insulation pattern.

In accordance with an aspect of the disclosure, a semiconductor device includes: a plurality of gate lines spaced apart in a vertical direction around a vertical hole; a channel layer extending in the vertical hole; a channel-side dielectric layer on an outer wall of the channel layer and extending in the vertical direction; a ferroelectric layer extending in the vertical direction between the channel-side dielectric layer and the plurality of gate lines; a plurality of charge trapping patterns spaced apart in the vertical direction, wherein each charge trapping pattern from among the plurality of charge trapping patterns is between the ferroelectric layer and a corresponding gate line from among the plurality of gate lines; a plurality of gate-side dielectric patterns separated in the vertical direction, wherein each gate-side dielectric pattern from among the plurality of gate-side dielectric patterns is between a corresponding charge trapping pattern from among the plurality of charge trapping patterns and the corresponding gate line; and a gap-fill insulation pattern comprising a plurality of first portions and a plurality of second portions, wherein each first portion from among the plurality of first portions is between a corresponding pair of adjacent gate lines from among the plurality of gate lines, and wherein the plurality of second portions extend from the plurality of first portions and are on the ferroelectric layer, wherein the plurality of second portions vertically overlap the plurality of charge trapping patterns and the plurality of gate-side dielectric patterns, wherein at least some of each second portion from among the plurality of second portions is longer than a corresponding first portion of the plurality of first portions in the vertical direction, and wherein a portion of a sidewall, facing the channel layer, of each gate line of the plurality of gate lines comprises a portion of the gap-fill insulation pattern facing a corresponding second portion of the plurality of second portions in a horizontal direction.

### BRIEF DESCRIPTION OF THE DRAWINGS

The above and other aspects, features, and advantages of certain embodiments of the present disclosure will be more apparent from the following description taken in conjunction with the accompanying drawings in which:

FIG. 1 is a block diagram of a semiconductor device according to embodiments;

FIG. 2A is a plan layout illustrating some elements of a cell array structure of a semiconductor device according to embodiments;

FIG. 2B is a cross-sectional view of some regions of a cross-sectional surface taken along line X1-X1′ of FIG. 2A;

FIG. 2C is an enlarged view of a region EXA1 of FIG. 2B;

FIG. 2D is an enlarged plan view of a partial region taken along line LV1-LV1′ of FIG. 2C;

FIG. 2E is an enlarged view of a region EXA2 of FIG. 2C;

FIG. 3 is a cross-sectional view for describing a semiconductor device according to embodiments;

FIG. 4 is a cross-sectional view for describing a semiconductor device according to embodiments;

FIG. 5A is a cross-sectional view for describing a semiconductor device according to embodiments;

FIG. 5B is an enlarged plan view of a partial region taken along line LV1-LV1′ of FIG. 5A;

FIG. 5C is an enlarged view of a region EXB1 of FIG. 5A;

FIG. 6A is a cross-sectional view for describing a semiconductor device according to embodiments;

FIG. 6B is an enlarged view of a region EXC1 of FIG. 6A;

FIG. 7 is a cross-sectional view for describing a semiconductor device according to embodiments;

FIG. 8 is a cross-sectional view for describing a semiconductor device according to embodiments;

FIG. 9 is a cross-sectional view for describing a semiconductor device according to embodiments;

FIG. 10 is a cross-sectional view for describing a semiconductor device according to embodiments;

FIG. 11 is a cross-sectional view for describing a semiconductor device according to embodiments;

FIG. 12 is a cross-sectional view for describing a semiconductor device according to embodiments;

FIG. 13 is a cross-sectional view for describing a semiconductor device according to embodiments;

FIGS. 14A to 14F are cross-sectional views illustrating in process sequence a method of manufacturing a semiconductor device, according to embodiments;

FIGS. 15A to 15D are cross-sectional views illustrating in process sequence a method of manufacturing a semiconductor device, according to embodiments;

FIGS. 16A to 16D are cross-sectional views illustrating in process sequence a method of manufacturing a semiconductor device, according to embodiments;

FIG. 17 is a cross-sectional view illustrating a method of manufacturing a semiconductor device, according to embodiments;

FIG. 18 is a diagram schematically illustrating an electronic system including a semiconductor device, according to an embodiment;

FIG. 19 is a perspective view schematically illustrating an electronic system including a semiconductor device, according to an embodiment; and

FIG. 20 is a cross-sectional view schematically illustrating semiconductor packages according to an embodiment.

### DETAILED DESCRIPTION OF THE EMBODIMENTS

Hereinafter, embodiments will be described in detail with reference to the accompanying drawings. Like reference numerals refer to like elements in the drawings, and redundant or duplicative descriptions may be omitted.

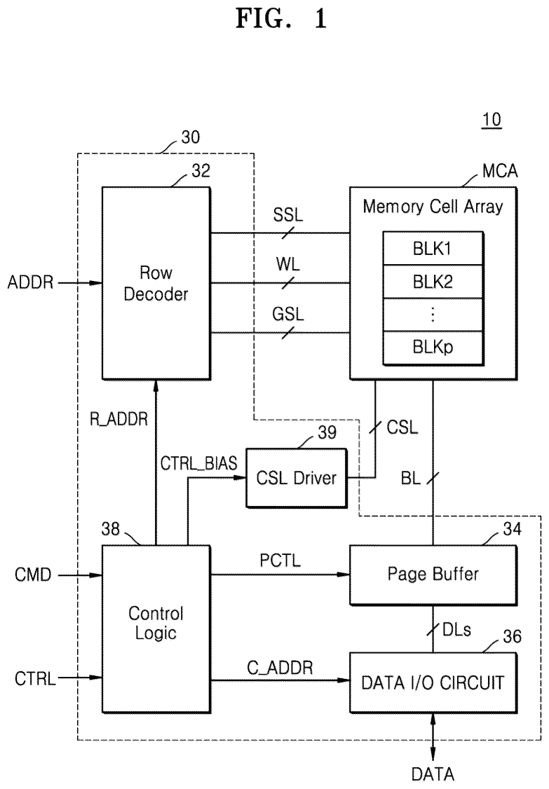

Referring to FIG. 1, a semiconductor device 10 may include a memory cell array MCA and a peripheral circuit 30. The memory cell array MCA may include a plurality of memory cell blocks BLK1, BLK2, . . . , and BLKp. Each of the plurality of memory cell blocks BLK1, BLK2, . . . , and BLKp may include a plurality of memory cells. The memory cell blocks BLK1, BLK2, . . . , and BLKp may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, a control logic 38, and a common source line driver 39. The peripheral circuit 30 may further include various circuits such as a voltage generating circuit which generates various voltages used for an operation of the semiconductor device 10, an error correction circuit for correcting an error of data read from the memory cell array MCA, and an I/O interface.

The memory cell array MCA may be connected to the row decoder 32 through the word line WL, the string selection line SSL, and the ground selection line GSL and may be connected to the page buffer 34 through the bit line BL. In the memory cell array MCA, each memory cell of the plurality of memory cells included in the plurality of memory cell blocks BLK1, BLK2, . . . , and BLKp may be a flash memory cell. The memory cell array MCA may include a three-dimensional (3D) memory cell array. The 3D memory cell array may include a plurality of NAND strings, and each of the plurality of NAND strings may include a plurality of memory cells respectively connected to a plurality of word lines WL, which may be vertically stacked.

The peripheral circuit 30 may receive an address ADDR, a command CMD, and a control signal CTRL from an outside of the semiconductor device 10 and may transfer or receive data DATA to or from a device outside the semiconductor device 10.

The row decoder 32 may select at least one memory cell block from among the plurality of memory cell blocks BLK1, BLK2, . . . , and BLKp based on the address ADDR from the outside and may select a word line WL, a string selection line SSL, and a ground selection line GSL of the selected memory cell block. The row decoder 32 may transfer a voltage, which may be used for performing a memory operation, to the word line WL of the selected memory cell block.

The page buffer 34 may be connected to the memory cell array MCA through the bit line BL. In a program operation, the page buffer 34 may operate a write driver to apply a voltage based on data DATA, which is to be stored in the memory cell array MCA, to the bit line BL, and in a read operation, the page buffer 34 may operate a sense amplifier to sense the data DATA stored in the memory cell array MCA. The page buffer 34 may operate based on the control signal CTRL provided from the control logic 38.

The data I/O circuit 36 may be connected to the page buffer 34 through a plurality of data lines DLs. In the program operation, the data I/O circuit 36 may receive data DATA from a memory controller and may provide program data DATA to the page buffer 34, based on a column address C_ADDR provided from the control logic 38. In the read operation, the data I/O circuit 36 may provide the memory controller with read data DATA stored in the page buffer 34, based on the column address C_ADDR provided from the control logic 38.

The data I/O circuit 36 may transfer an address or a command, input thereto, to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data I/O circuit 36. The control logic 38 may generate various internal control signals used in the semiconductor device 10 based on the control signal CTRL. For example, the control logic 38 may adjust a voltage level provided to the word line WL and the bit line BL when performing a memory operation such as a program operation or an erase operation.

The common source line driver 39 may be connected to the memory cell array MCA through the common source line CSL. The common source line driver 39 may apply a common source voltage (for example, a source voltage) or a ground voltage to the common source line CSL, based on a control signal CTRL_BIAS of the control logic 38.

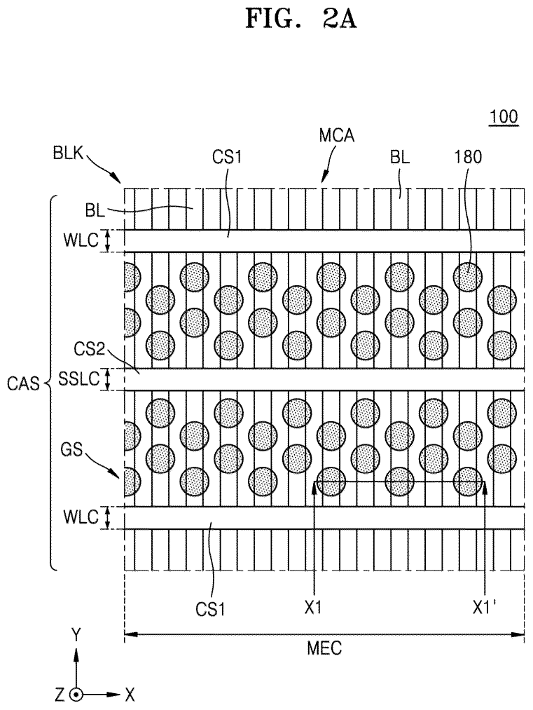

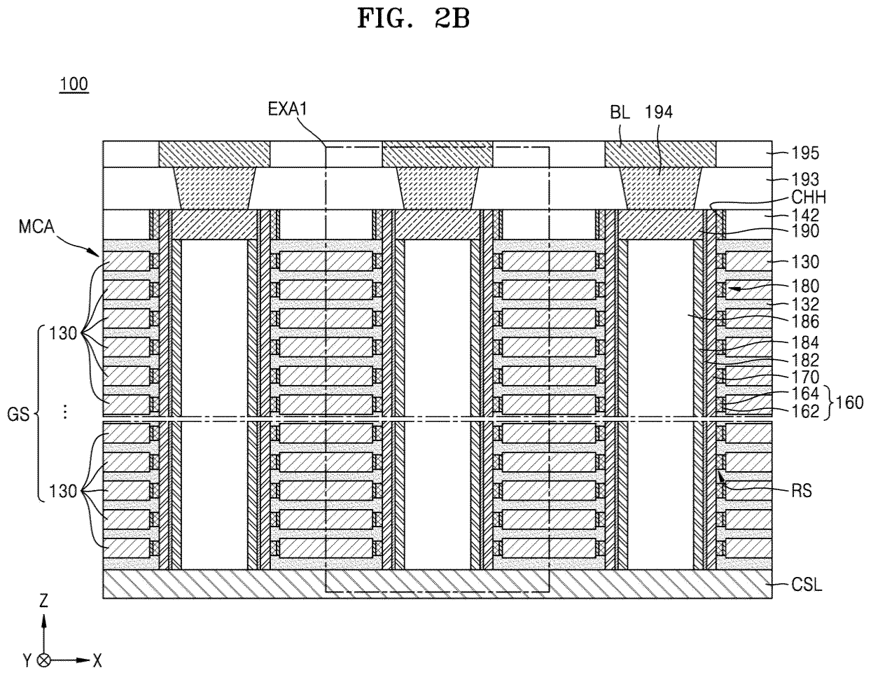

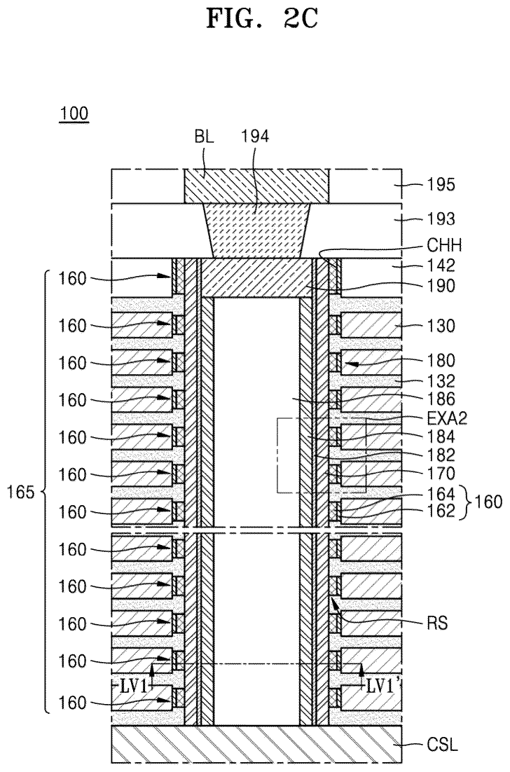

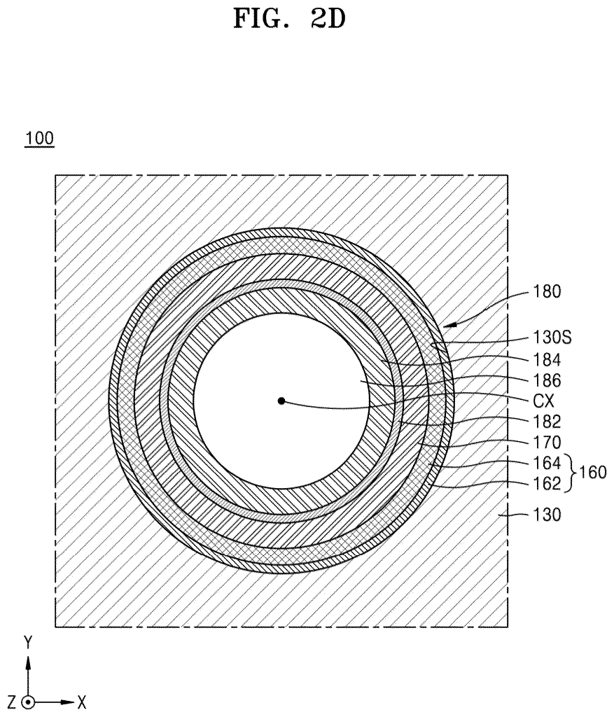

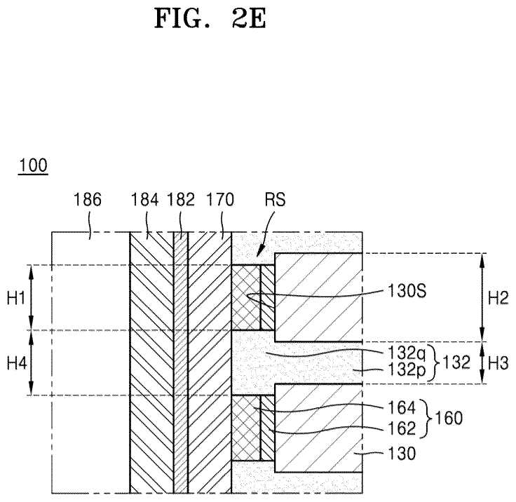

FIG. 2A is a plan layout illustrating some elements of a cell array structure CAS of a semiconductor device 100 according to embodiments. FIG. 2B is a cross-sectional view of some regions of a cross-sectional surface taken along line X1-X1′ of FIG. 2A in the cell array structure CAS of the semiconductor device 100. FIG. 2C is an enlarged view of a region EXA1 of FIG. 2B. FIG. 2D is an enlarged plan view of a partial region taken along line LV1-LV1′ of FIG. 2C. FIG. 2E is an enlarged view of a region EXA2 of FIG. 2C. In FIGS. 2A and 2B, some elements of a memory cell block BLK corresponding to one memory cell block from among the plurality of memory cell blocks BLK1, BLK2, . . . , and BLKp illustrated in FIG. 1 is illustrated.

Referring to FIGS. 2A to 2E, the semiconductor device 100 may include a cell array structure CAS, and the cell array structure CAS may include a common source line CSL disposed in a memory cell region MEC and a memory cell array MCA disposed on the common source line CSL in the memory cell region MEC. Herein, the common source line CSL may be referred to as a conductive layer.

According to embodiments, the memory cell array MCA may include a gate stack GS including a plurality of gate lines 130. The plurality of gate lines 130 may extend in a horizontal direction parallel to the common source line CSL, and may overlap each other in a vertical direction (e.g., a Z direction). The plurality of gate lines 130 may include the plurality of word lines WL, the ground selection line GSL, and the string selection line SSL each illustrated in FIG. 1.

As illustrated in FIG. 2B, the cell array structure CAS may include a stack structure including the plurality of gate lines 130 and a gap-fill insulation pattern 132 filling a space between the plurality of gate lines 130. The gate stack GS may include the plurality of gate lines 130 which overlap each other in the vertical direction (e.g., the Z direction) and may be apart from one another in the vertical direction (e.g., the Z direction), on the common source line CSL. In embodiments, a plurality of elements which are described as being apart from one another or each other may be spaced apart (e.g., spaced apart from each other or one another) or may be arranged to be apart (e.g., arranged to be apart from each other or one another). For example, each element of the plurality of elements may be spaced or arranged to be apart from all of the other elements of the plurality of elements, and there may be a space or other separation between each element of the plurality of elements. The gap-fill insulation pattern 132 may fill a space between the common source line CSL and the plurality of gate lines 130 and a space between two adjacent gate lines 130 of the plurality of gate lines 130. The stack structure may further include a middle insulation layer 142 on (or for example covering) the gap-fill insulation pattern 132. For example, the gap-fill insulation pattern 132 may include a portion disposed between the middle insulation layer 142 and a gate line 130 farthest away from the common source line CSL from among the plurality of gate lines 130. In some embodiments, each of the gap-fill insulation pattern 132 and the middle insulation layer 142 may include silicon oxide, silicon nitride, or SiON.

In some embodiments, each of the plurality of gate lines 130 may include metal, conductive metal nitride, metal silicide, an impurity-doped semiconductor, or a combination thereof. For example, each of the plurality of gate lines 130 may include tungsten, nickel, cobalt, tantalum, tungsten nitride, titanium nitride, tantalum nitride, doped polysilicon, tungsten silicide, nickel silicide, cobalt silicide, tantalum silicide, or a combination thereof, but embodiments are not limited thereto.

According to embodiments, the semiconductor device 100 may include a plurality of conductive pads 190 which may be apart from the common source line CSL in the vertical direction (e.g., the Z direction) with the stack structure, including the plurality of gate lines 130 and the gap-fill insulation pattern 132, therebetween.

In some embodiments, each of the common source line CSL and the plurality of conductive pads 190 may include a semiconductor material, metal, conductive metal nitride, or a combination thereof. For example, each of the common source line CSL and the plurality of conductive pads 190 may include doped polysilicon, tungsten, titanium, tantalum, copper, aluminum, titanium nitride, tantalum nitride, tungsten nitride, or a combination thereof, but embodiments are not limited thereto.

The cell array structure CAS may include a plurality of channel structures 180 respectively disposed in a plurality of vertical holes CHH passing through the stack structure in the vertical direction (e.g., the Z direction). According to embodiments, the plurality of channel structures 180 may pass through the plurality of gate lines 130 and the gap-fill insulation pattern 132 in the vertical direction (e.g., the Z direction). According to embodiments, each of the plurality of channel structures 180 may include a composite dielectric layer, a channel layer 184, and an insulation plug 186, which may be sequentially stacked in a direction toward a center CX of the channel structure 180 from the plurality of gate lines 130. The composite dielectric layer may include a boundary dielectric layer 165, a ferroelectric layer 170, and a channel-side dielectric layer 182, which may be sequentially stacked in the direction toward the center CX of the channel structure 180 from the plurality of gate lines 130.

According to embodiments, the channel layer 184 may extend lengthwise in the vertical direction (e.g., the Z direction) in the vertical hole CHH. According to embodiments, the channel layer 184 may be on one conductive pad 190 from among the plurality of conductive pads 190. In embodiments, a first element described herein as “on” a second element may be directly or indirectly on the second element. For example, the first element may directly contact the second element, or there may be intervening elements between the first element and the second element. One end portion of the channel layer 184 in the vertical direction (e.g., the Z direction) may be on the conductive pad 190, and the other end portion of the channel layer 184 may be on the common source line CSL. In some embodiments, the channel layer 184 may have a cylinder shape to define a pillar-shaped space which extends lengthwise in the vertical direction (e.g., the Z direction) therein.

According to embodiments, the insulation plug 168 may be disposed in the pillar-shaped space defined by the channel layer 184, and the channel layer 184 may be around (or for example surround) the insulation plug 168. For example, the insulation plug 168 may fill a space between the conductive pad 190 and the common source line CSL, in the pillar-shaped space defined by the channel layer 184. The insulation plug 168 may include a surface on the inner wall of the channel layer 184. In some embodiments, the insulation plug 168 may include silicon oxide, but embodiments are not limited thereto.

In some embodiments, the channel layer 184 may include polysilicon, an oxide semiconductor, a two-dimensional (2D) semiconductor material, or a combination thereof. The polysilicon may include doped polysilicon, but embodiments are not limited thereto.

In some embodiments, the oxide semiconductor capable of being used to configure the channel layer 184 may be at least one from among IGZO (InGaZnO), Sn-IGZO, IWO (InWO), IZO (InZnO), ZTO (ZnSnO), ZnO, YZO (yttrium-doped zinc oxide), IGSO (InGaSiO), InO, SnO, TiO, ZnON, MgZnO, ZrInZnO, HfInZnO, SnInZnO, SiInZnO, GaZnSnO, and ZrZnSnO, or a combination thereof. In some embodiments, at least a portion of the channel layer 184 may include the same elements as those included in the oxide semiconductor layer, and may further include at least one dopant from among aluminum (Al), boron (B), arsenic (As), fluoride (F), and hydrogen (H).

In some embodiments, the 2D semiconductor material capable of being used to configure the channel layer 184 may be at least one from among graphene, black phosphorous, and a transition metal chalcogen compound, or a combination thereof. The transition metal chalcogen compound may include a combination of transition metal, from among nickel (Ni), copper (Cu), zinc (Zn), molybdenum (Mo), tungsten (W), niobium (Nb), vanadium (V), tantalum (Ta), titanium (Ti), zirconium (Zr), hafnium (Hf), technetium (Tc), and rhenium (Re), and a chalcogen-group element from among sulfur(S), selenium (Se), and tellurium (Te). For example, the channel layer 184 may include MoS₂, MoSe₂, MoTe₂, WS₂, WSe₂, WTe₂, ZrS₂, ZrSe₂, HfS₂, HfSe₂, NbSe₂, ReSe₂, CuS, or a combination thereof, but embodiments are not limited thereto.

In some other embodiments, the 2D semiconductor material capable of being used to configure the channel layer 184 may include a chalcogenide material including non-transition metal. The non-transition metal may be at least one from among gallium (Ga), indium (In), tin (Sn), germanium (Ge), and lead (Pb). For example, the channel layer 184 may include SnSe₂, GaS, GaSe, GaTe, GeSe, In₂Se₃, InSnS₂, or a combination thereof, but embodiments are not limited thereto.

In some other embodiments, the channel layer 184 may include a p-type oxide semiconductor, an n-type oxide semiconductor, or a combination thereof. The p-type oxide semiconductor may be at least one from among nickel oxide (NiO), copper oxide, tin oxide (SnO), copper aluminum dioxide (CuAlO₂), copper chrome dioxide (CuCrO₂), and beta tellurium dioxide (β-TeO₂), or a combination thereof. The copper oxide may include CuO or Cu₂O, but embodiments are not limited thereto. The n-type oxide semiconductor may be at least one from among indium oxide (In₂O₃), tin dioxide (SnO₂), zinc oxide (ZnO), and IGZO, or a combination thereof. When the tin oxide is in the form of SnO, the tin oxide may represent a p-type characteristic, and when the tin oxide is in the form of SnO₂, the tin oxide may represent an n-type characteristic.

According to embodiments, the channel-side dielectric layer 182 may be on (or for example covering) an outer wall of the channel layer 184 and may extend lengthwise in the vertical direction (e.g., the Z direction), in the vertical hole CHH. For example, the channel-side dielectric layer 182 may include a portion disposed between the plurality of gate lines 130 and the channel layer 184 and a portion disposed between the gap-fill insulation pattern 132 and the channel layer 184. According to embodiments, the channel-side dielectric layer 182 may include an inner wall on the outer wall of the channel layer 184. In some embodiments, the channel-side dielectric layer 182 may include a first end portion and a second end portion, which may be opposite to each other in the vertical direction (e.g., the Z direction). The first end portion of the channel-side dielectric layer 182 may be on the conductive pad 190, and the second end portion of the channel-side dielectric layer 182 may be on the common source line CSL. In some embodiments, in the first end portion of the channel-side dielectric layer 182, the channel-side dielectric layer 182 may be around (or for example may surround) a sidewall of the conductive pad 190.

In some embodiments, the channel-side dielectric layer 182 may include silicon oxide, silicon oxynitride, a high-k dielectric material having a dielectric constant which is higher than a dielectric constant of silicon oxide, or a combination thereof. The high-k dielectric material may include metal oxide. The high-k dielectric material may include aluminum oxide (Al₂O₃), but embodiments are not limited thereto.

In some embodiments, the channel layer 184 may have a thickness of about 5nanometers (nm) to about 20 nm in a horizontal direction, but embodiments are not limited thereto. In some embodiments, a thickness of the channel-side dielectric layer 182 in the horizontal direction may be within a range of about 0.1 nm to about 10 nm, but embodiments are not limited thereto. Herein, a thickness of an element configuring the channel structure 180 in the horizontal direction may denote the difference between a distance between the center CX and an outer wall of the element and a distance between the center CX and an inner wall of the element.

According to embodiments, the ferroelectric layer 170 may be on (or for example covering) an outer wall of the channel-side dielectric layer 182 and may extend lengthwise in the vertical direction (e.g., the Z direction), in the vertical hole CHH. For example, the ferroelectric layer 170 may include a portion disposed between the plurality of gate lines 130 and the channel layer 184 and a portion disposed between the gap-fill insulation pattern 132 and the channel layer 184. The channel-side dielectric layer 182 may be disposed between the ferroelectric layer 170 and the channel layer 184. For example, the ferroelectric layer 170 may include an inner wall on the outer wall of the channel-side dielectric layer 182. In some embodiments, the ferroelectric layer 170 may include a first end portion and a second end portion, which may be opposite to each other in the vertical direction (e.g., the Z direction). In the first end portion of the ferroelectric layer 170, the inner wall of the ferroelectric layer 170 may be apart from the sidewall of the conductive pad 190 with the channel-side dielectric layer 182 therebetween. According to embodiments, the second end portion of the ferroelectric layer 170 may be on the common source line CSL.

In some embodiments, the ferroelectric layer 170 may include at least one oxide from among Hf, Si, Al, Zr, Y, La, Gd, and Sr. For example, the ferroelectric layer 170 may include hafnium oxide (HfO), hafnium zirconium oxide (HZO), hafnium titanium oxide, or hafnium silicon oxide. Herein, HfO may denote a material which includes elements included in each term and may not be a chemical formula representing a stoichiometry relationship. For example, the ferroelectric layer 170 may include hafnium dioxide (HfO₂). In some embodiments, the ferroelectric layer 170 may further include a dopant. The dopant may include at least one element from among Si, Al, Zr, Y, La, Gd, Sc, Sr, Mg, and Ba, but embodiments are not limited thereto. In some embodiments, the ferroelectric layer 170 may be within a thickness range of about 5 nm to about 20 nm in the horizontal direction, but embodiments are not limited thereto. In some embodiments, a thickness of the channel structure 180 in the horizontal direction may be substantially constant in the vertical direction (e.g., the Z direction).

In some embodiments, each of the ferroelectric layer 170, the channel-side dielectric layer 182, and the channel layer 184 may have a hollow cylindrical structure. In some embodiments, the channel-side dielectric layer 182 may be disposed in a space defined by the ferroelectric layer 170, and the channel layer 184 may be disposed in a space defined by the channel-side dielectric layer 182.

According to embodiments, the boundary dielectric layer 165 may include a plurality of boundary dielectric patterns 160 which may be apart from one another in the vertical direction (e.g., the Z direction) and which may each be disposed between the ferroelectric layer 170 and a corresponding gate line 130 of the plurality of gate lines 130. For example, each of the plurality of boundary dielectric patterns 160 may be disposed between the ferroelectric layer 170 and one gate line 130 from among the plurality of gate lines 130. In some embodiments, the ferroelectric layer 170 may face the plurality of gate lines 130 with the plurality of boundary dielectric patterns 160 therebetween. According to embodiments, each of the plurality of boundary dielectric patterns 160 may include an inner wall on the ferroelectric layer 170 and an outer wall on a corresponding gate line 130 of the plurality of gate lines 130. According to embodiments, an uppermost boundary dielectric pattern 160 of the plurality of boundary dielectric patterns 160 in the vertical direction (e.g., the Z direction) may be disposed between the ferroelectric layer 170 and the middle insulation layer 142 and may include an inner wall on the ferroelectric layer 170 and an outer wall on the middle insulation layer 142.

For example, the plurality of boundary dielectric patterns 160 may include a plurality of ring shapes which may be around (or for example may surround) the ferroelectric layer 170 and may be apart from one another in the vertical direction (e.g., the Z direction). For example, in a plan view, the channel layer 184, the channel-side dielectric layer 182, the ferroelectric layer 170, and the plurality of boundary dielectric patterns 160 may have a concentric circle shape. However, embodiments are not limited thereto, and for example, the channel layer 184, the channel-side dielectric layer 182, the ferroelectric layer 170, and the plurality of boundary dielectric patterns 160 may have a concentric tetragonal shape or a concentric oval shape.

According to embodiments, the gap-fill insulation pattern 132 may be disposed between the plurality of boundary dielectric patterns 160 apart from one another in the vertical direction (e.g., the Z direction). According to embodiments, the plurality of boundary dielectric patterns 160 may include a surface which faces the gap-fill insulation pattern 132 in the vertical direction (e.g., the Z direction). For example, each of an upper surface and a lower surface of each of the plurality of boundary dielectric patterns 160 in the vertical direction (e.g., the Z direction) may be on the gap-fill insulation pattern 132. Unless described herein, an upper surface may denote a surface which faces an upper side in the drawing, and a lower surface may denote a surface which faces a lower side in the drawing.

According to embodiments, the gap-fill insulation pattern 132 may include a portion which is on the ferroelectric layer 170 between the plurality of boundary dielectric patterns 160. In some embodiments, the ferroelectric layer 170 may extend lengthwise in the vertical direction (e.g., the Z direction) in a space defined by the gap-fill insulation pattern 132 and the plurality of boundary dielectric patterns 160.

According to embodiments, a first height H1 of each of the plurality of boundary dielectric patterns 160 in the vertical direction (e.g., the Z direction) may be less than a second height H2 of each of the plurality of gate lines 130 in the vertical direction (e.g., the Z direction). In some embodiments, an upper surface of each of the plurality of boundary dielectric patterns 160 may be at a vertical level which may be lower than an upper surface of a corresponding gate line 130 of the plurality of gate lines 130, and a lower surface thereof may be at a vertical level which may be higher than a lower surface of the corresponding gate line 130.

According to embodiments, a sidewall 130S of each of the plurality of gate lines 130 may include a portion facing a corresponding boundary dielectric pattern 160 of the plurality of boundary dielectric patterns 160 in the horizontal direction (e.g., an X direction and/or a Y direction) and a portion facing the gap-fill insulation pattern 132. In some embodiments, the sidewall 130S of each of the plurality of gate lines 130 may include a portion facing an outer wall of a corresponding boundary dielectric pattern 160 of the plurality of boundary dielectric patterns 160 and a portion facing the gap-fill insulation pattern 132. In some embodiments, a recess RS may be defined by a portion of the outer wall of the ferroelectric layer 170, an upper surface of a first boundary dielectric pattern 160 of the plurality of dielectric patterns and a lower surface of a second boundary dielectric pattern 160 of the plurality of boundary dielectric patterns 160 facing the upper surface of the first boundary dielectric pattern 160, and a portion of the sidewall 130S of each of two gate lines 130 each on the first boundary dielectric pattern 160 and the second boundary dielectric pattern 160. In some embodiments, a plurality of recesses RS may be filled by the gap-fill insulation pattern 132. The first boundary dielectric pattern 160 and the second dielectric pattern 160 may be apart from each other with the gap-fill insulation pattern 132 therebetween.

According to embodiments, the gap-fill insulation pattern 132 may include a plurality of first portions 132p vertically overlapping the plurality of gate lines 130 and a plurality of second portions 132q vertically overlapping the plurality of boundary dielectric patterns 160. According to embodiments, the plurality of first portions 132p may be disposed one-by-one between the plurality of gate lines 130 apart from one another in the vertical direction (e.g., the Z direction), between an uppermost gate line 130 and the middle insulation layer 142, and between a lowermost gate line 130 and the common source line CSL. The plurality of second portions 132q may be disposed one-by-one between the plurality of boundary insulation patterns 160 apart from one another in the vertical direction (e.g., the Z direction) and between a lowermost boundary insulation pattern 160 and the common source line CSL.

According to embodiments, each of the plurality of second portions 132q may include a portion having a length in the vertical direction (e.g., the Z direction) which is greater than a length of a corresponding first portion 132p of the plurality of first portions 132p. In some embodiments, a third height H3, which may correspond to a length of each the plurality of first portions 132p in the vertical direction (e.g., the Z direction), may be less than a fourth height H4, which may correspond to a length of each of the plurality of second portions 132q in the vertical direction (e.g., the Z direction).

According to embodiments, the plurality of second portions 132q may fill the recess RS at one side or both sides thereof in the vertical direction (e.g., the Z direction). In some embodiments, the plurality of second portions 132q may include a portion on the ferroelectric layer 170, a portion on the plurality of boundary dielectric patterns 160, and a portion on a portion of the sidewall 130S of each of the plurality of gate lines 130. For example, the sidewall 130S of each of the plurality of gate lines 130 may include a portion facing the ferroelectric layer 170 in the horizontal direction with a second portion 132q of the plurality of second portions 132q of the gap-fill insulation pattern 132 therebetween.

According to embodiments, each of the plurality of boundary dielectric patterns 160 may include a charge trapping pattern 164 and a gate-side dielectric pattern 162, which may be sequentially stacked in a direction toward the plurality of gate lines 130 from the center CX of the channel structure 180. In some embodiments, the charge trapping pattern 164 may include an inner wall on the outer wall of the ferroelectric layer 170 and an outer wall on the inner wall of the gate-side dielectric pattern 162. In some embodiments, the gate-side dielectric pattern 162 may be disposed between the charge trapping pattern 164 and one gate line 130 from among the plurality of gate lines 130. In some embodiments, the gate-side dielectric pattern 162 may be on a portion of the sidewall 130S of one gate line 130 from among the plurality of gate lines 130.

According to embodiments, each of the charge trapping pattern 164 and the gate-side dielectric pattern 162 may include a surface on the gap-fill insulation pattern 132. For example, an upper surface and a lower surface of each of the charge trapping pattern 164 and the gate-side dielectric pattern 162 may define the recess RS and may be on the second portion 132q of the gap-fill insulation pattern 132.

In some embodiments, the charge trapping pattern 164 may include at least one material from among silicon oxide, silicon nitride, silicon oxynitride, an oxide/nitride/oxide (ONO) multilayer, a high-k dielectric material having a dielectric constant which is higher than a dielectric constant of silicon oxide, and nano-crystal including a compound semiconductor. The high-k dielectric material may include aluminum oxide and hafnium oxide. The nano-crystal may include at least one quantum dot from among CdSe, ZnTe, CdS, ZnS, ZnSe, and HgCdTe each having a charge trapping characteristic. In some embodiments, the gate-side dielectric layer 162 may include silicon oxide, silicon oxynitride, a high-k dielectric material having a dielectric constant which is higher than a dielectric constant of silicon oxide, or a combination thereof. The high-k dielectric material may include, for example, metal oxide (for example, Al₂O₃), but embodiments are not limited thereto.

In some embodiments, the charge trapping pattern 164 may have a thickness of about 1 nm to about 10 nm in the horizontal direction, but embodiments are not limited thereto. In some embodiments, the gate-side dielectric pattern 162 may have a thickness of about 0.1 nm to about 10 nm in the horizontal direction, but embodiments are not limited thereto. A thickness of each of the channel layer 184, the channel-side dielectric layer 182, the ferroelectric layer 170, and the gate-side dielectric pattern 162 in the horizontal direction is not limited to the above description and may be variously changed within the scope of the disclosure.

In FIGS. 2B, 2C, and 2E, lengths of the charge trapping pattern 164 and the gate-side dielectric pattern 162 in the vertical direction (e.g., the Z direction) may be equal to each other, but embodiments are not limited thereto. In some embodiments, a length of the charge trapping pattern 164 in the vertical direction (e.g., the Z direction) may be greater than a length of the gate-side dielectric pattern 162 in the vertical direction (e.g., the Z direction). In some other embodiments, a length of the charge trapping pattern 164 in the vertical direction (e.g., the Z direction) may be less than a length of the gate-side dielectric pattern 162 in the vertical direction (e.g., the Z direction).

In some embodiments, the charge trapping pattern 164 and the gate-side dielectric pattern 162 may include different materials. For example, the charge trapping pattern 164 may include silicon nitride and the gate-side dielectric pattern 162 may include silicon oxide. In some embodiments, the charge trapping pattern 164 and the gate-side dielectric pattern 162 may include the same material. In this case, each of the plurality of boundary dielectric patterns 160 may include a single material layer.

According to embodiments, a plurality of bit lines BL may be disposed on the plurality of channel structures 180 in the cell array structure CAS. A plurality of bit line contact pads 194 may be disposed between the plurality of channel structures 180 and the plurality of bit lines BL. The conductive pad 190 disposed on one end portion of each of the plurality of channel structures 180 may be connected to one corresponding bit line BL of the plurality of bit lines BL through the bit line contact pad 194. In some embodiments, the plurality of bit line contact pads 194 may be insulated from one another by a first upper insulation layer 193, and the plurality of bit lines BL may be insulated from one another by a second upper insulation layer 195.

In some embodiments, each of the plurality of bit line contact pads 194 and the plurality of bit lines BL may include metal, conductive metal nitride, or a combination thereof. For example, each of the plurality of bit line contact pads 194 and the plurality of bit lines BL may include tungsten, titanium, tantalum, copper, aluminum, titanium nitride, tantalum nitride, tungsten nitride, or a combination thereof. Each of the first upper insulation layer 193 and the second upper insulation layer 195 may include silicon oxide, silicon nitride, or a combination thereof.

As illustrated in FIG. 2A, a plurality of word line cut regions WLC may extend in a first horizontal direction (e.g., the X direction) in the cell array structure CAS. The plurality of word line cut regions WLC may define a width of the gate stack GS in a second horizontal direction (e.g., the Y direction). The plurality of word line cut regions WLC may be filled with a word line cut structure CS1. The word line cut structure CS1 may include an insulation layer, polysilicon, a metal layer, or a combination thereof. In some embodiments, the word line cut structure CS1 may include a silicon oxide layer, a silicon nitride layer, a polysilicon layer, a tungsten layer, or a combination thereof, but embodiments are not limited thereto.

In some embodiments, at least a portion of the word line cut structure CS1 may configure a structure provided as one body with the gap-fill insulation pattern 132. In some embodiments, the word line cut structure CS1 may be formed together in the same process as the gap-fill insulation pattern 132. For example, the word line cut structure CS1 may include a material configuring the gap-fill insulation pattern 132.

According to embodiments, in the memory cell array MCA, two string selection lines SSL (as shown for example in FIG. 1) adjacent to each other in the second horizontal direction (e.g., the Y direction) may be apart from each other with a string selection line cut region SSLC therebetween. The string selection line cut region SSLC may be filled with a string selection line cut structure CS2. The string selection line cut structure CS2 may include oxide, nitride, or a combination thereof. In some embodiments, at least a portion of the string selection line cut region SSLC may include an air gap. The term “air” used herein may denote different gases which may be in an atmosphere or a manufacturing process.

Each of the plurality of channel structures 180 included in the semiconductor device 100 according to embodiments may include the boundary dielectric layer 165, the ferroelectric layer 170, the channel-side dielectric layer 182, the channel layer 184, and the insulation plug 186, which may be sequentially stacked in a direction toward the center CX of the channel structure 180 from the plurality of gate lines 130. In the semiconductor device 100 according to embodiments, the ferroelectric layer 170 having a polarization characteristic and the boundary dielectric layer 165 having a charge trapping characteristic may be disposed between the channel layer 184 and the plurality of gate lines 130, and thus, a memory window of the semiconductor device 100 may increase and electrical reliability may be enhanced. The boundary dielectric layer 165 of the semiconductor device 100 according to embodiments may include the plurality of boundary dielectric patterns 160 which may be apart from one another in the vertical direction (e.g., the Z direction). A plurality of memory cells included in the semiconductor device 100 may share the ferroelectric layer 170 and may each include at least one of the plurality of boundary dielectric patterns 160 which may be apart from one another in the vertical direction (e.g., the Z direction). The semiconductor device 100 according to embodiments may decrease the loss rate of trapped electric charges in the plurality of boundary dielectric patterns 160, even as an interval between cells adjacent to each other in the vertical direction (e.g., the Z direction) is reduced, and may maintain and reinforce a polarization characteristic of the ferroelectric layer 170. Accordingly, a memory retention characteristic of the semiconductor device 100 may be enhanced, and the stability and reliability of the semiconductor device 100 may be enhanced.

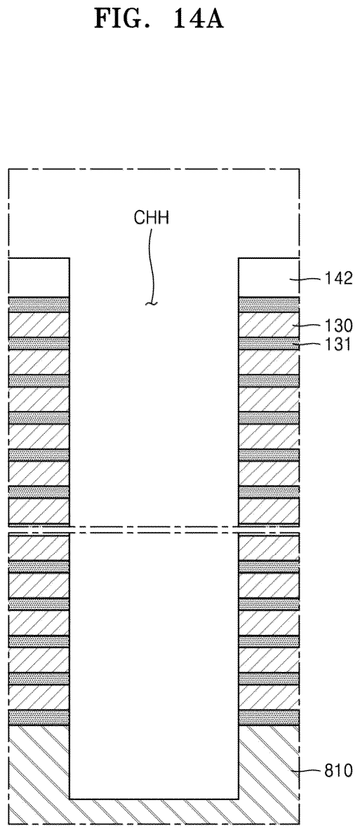

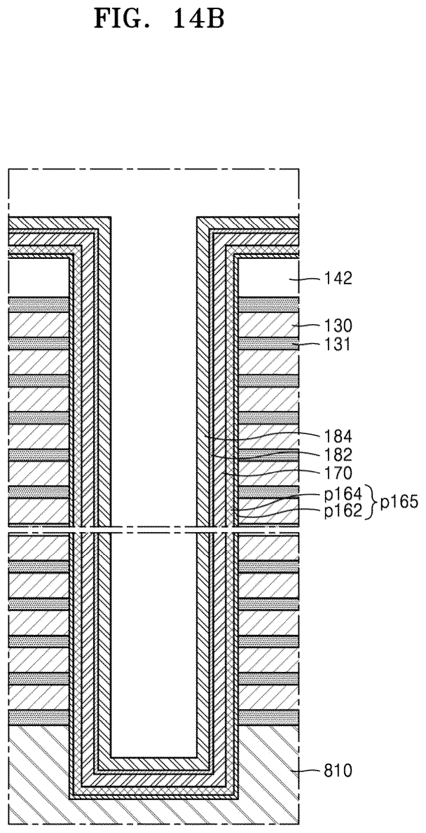

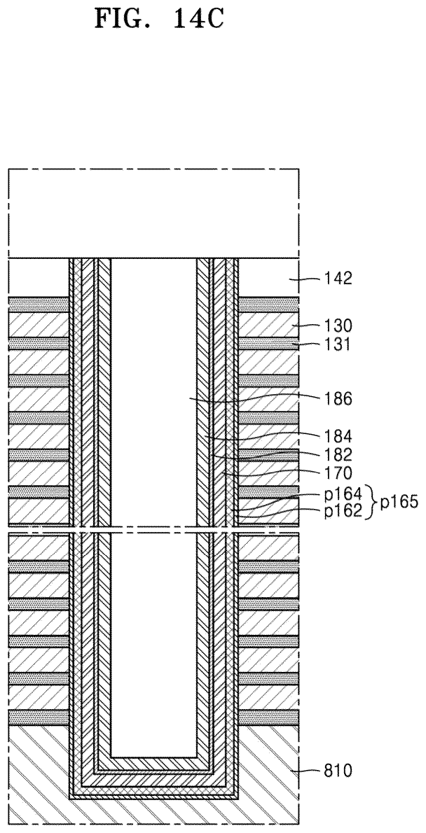

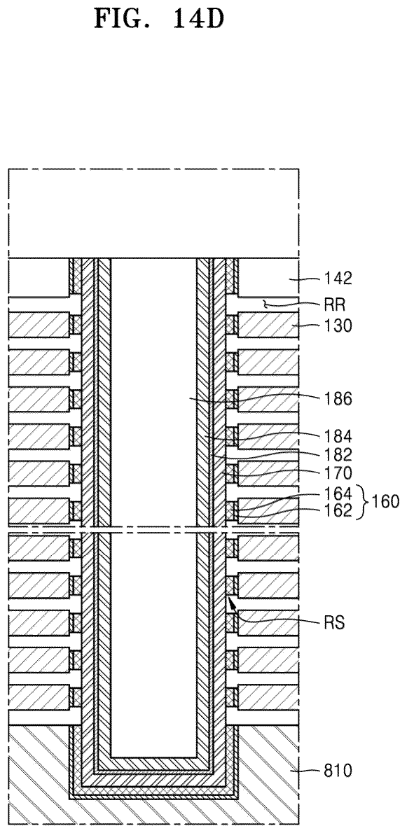

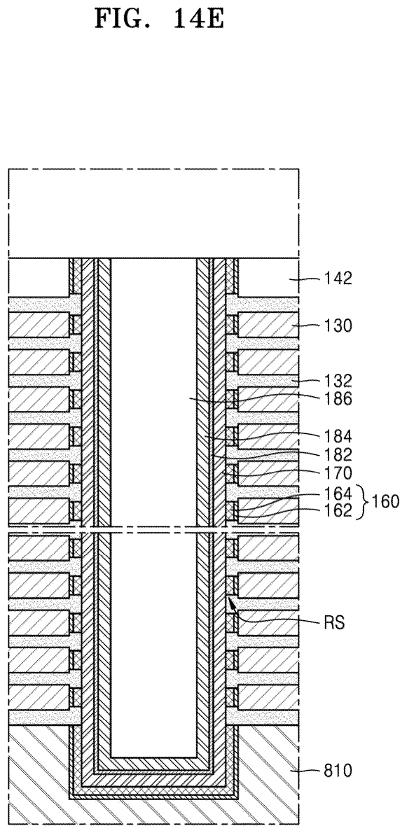

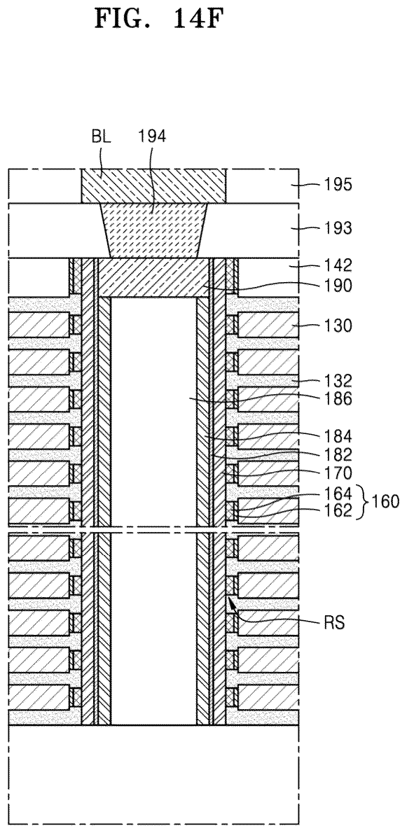

Also, the plurality of boundary dielectric patterns 160 included in the semiconductor device 100 according to embodiments may be formed by an etching process using a space between the plurality of gate lines 130 after a preliminary boundary dielectric layer p165 (as shown for example in FIG. 14B) extending in the vertical direction (e.g., the Z direction) is formed, and in such a process, a portion of the sidewall 130S of each of the plurality of gate lines 130 may be exposed and may be partially or entirely covered by the gap-fill insulation pattern 132. In the semiconductor device 100 according to embodiments, even when the size of each of a plurality of cells is reduced through high integration, a thickness of each of the plurality of boundary dielectric patterns 160 in the horizontal direction may be adjusted at a low process difficulty level and a thickness of each of the plurality of boundary dielectric patterns 160 in the horizontal direction may be uniformly implemented.

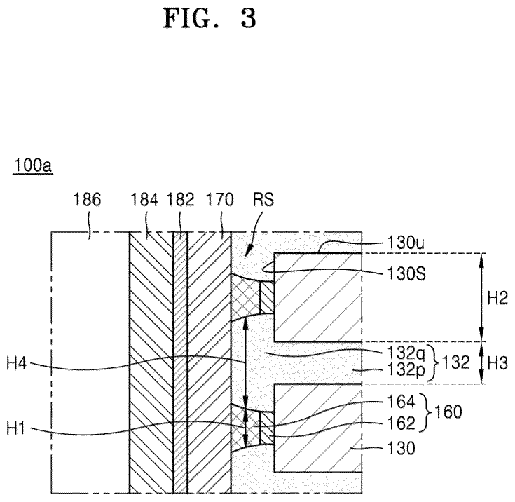

FIG. 3 is a cross-sectional view for describing a semiconductor device 100a according to embodiments. In FIG. 3, an enlarged cross-sectional configuration of a portion corresponding to a region EXA2 of FIG. 2C in the semiconductor device 100a is illustrated. In FIG. 3, the same reference numerals as FIGS. 2A to 2E refer to like elements, and redundant or duplicative descriptions thereof may be omitted.

Referring to FIG. 3, the semiconductor device 100a may have substantially the same configuration as the semiconductor device 100 described above with reference to FIGS. 2A to 2E. In the semiconductor device 100a, a surface of each of a plurality of boundary dielectric patterns 160 which faces a gap-fill insulation pattern 132 may have a slope with respect to an upper surface 130u of each of a plurality of gate lines 130.

In some embodiments, the plurality of gate lines 130 may extend in a horizontal direction (e.g., an X direction and/or a Y direction) and may each include the upper surface 130u and a lower surface which may be parallel to each other. In some embodiments, each of an upper surface and a lower surface, on the gap-fill insulation pattern 132, of each of a plurality of boundary dielectric patterns 160 may have a slope with respect to the upper surface 130u of a corresponding gate line 130 of the plurality of gate lines 130.

In some embodiments, a first height H1, which may correspond to a length of each of the plurality of boundary dielectric patterns 160 in a vertical direction (e.g., the Z direction), may decrease progressively toward the plurality of gate lines 130. In some embodiments, the upper surface of each of the plurality of boundary dielectric patterns 160 may have a downward slope in a direction away from a ferroelectric layer 170, and a vertical level of the upper surface of each of the plurality of boundary dielectric pattern 160 may be lower as the distance from the ferroelectric layer 170 increases.

In some embodiments, the lower surface of each of the plurality of boundary dielectric patterns 160 may have an upward slope in a direction away from the ferroelectric layer 170, and a vertical level of the lower surface of each of the plurality of boundary dielectric pattern 160 may be higher as the distance from the ferroelectric layer 170 increases. In some embodiments, each of the upper surface and the lower surface of each of the plurality of boundary dielectric patterns 160 may have a curved shape.

In some embodiments, a surface of a charge trapping pattern 164 on the gap-fill insulation pattern 132 may have a slope with respect to the upper surface 130u of the gate line 130 and may have a curved shape. In some embodiments, a vertical length of the charge trapping pattern 164 may decrease progressively in a direction away from the ferroelectric layer 170 in a horizontal direction.

In some embodiments, a surface of a gate-side dielectric pattern 162 on the gap-fill insulation pattern 132 may have a slope with respect to the upper surface 130u of the gate line 130 and may have a curved shape. In some embodiments, a vertical length of the gate-side dielectric pattern 162 may decrease progressively in a direction away from the ferroelectric layer 170 in the horizontal direction.

In some embodiments, each of an upper surface and a lower surface of each of a plurality of second portions 132q of the gap-fill insulation pattern 132 may have a profile corresponding to the upper surface and/or the lower surface of each of the plurality of boundary dielectric patterns 160. For example, a fourth height H4, which may correspond to a length of each of the plurality of second portions 132q of the gap-fill insulation pattern 132 in the vertical direction (e.g., the Z direction), may decrease progressively toward the ferroelectric layer 170. For example, each of the upper surface and the lower surface of each of the plurality of second portions 132q of the gap-fill insulation pattern 132 may have a slope with respect to the upper surface 130u of the gate line 130. In some embodiments, for example, each of the upper surface and the lower surface of each of the plurality of second portions 132q of the gap-fill insulation pattern 132 may have a curved shape.

FIG. 3 illustrates an example in which a length of an outer wall of the charge trapping pattern 164 in the vertical direction (e.g., the Z direction) is equal to that of an inner wall of the gate-side dielectric pattern 162 in the vertical direction (e.g., the Z direction), and an average vertical length of the charge trapping pattern 164 in the horizontal direction is greater than an average vertical length of the gate-side dielectric pattern 162 in the horizontal direction, but embodiments are not limited thereto. In some embodiments, a length of the outer wall of the charge trapping pattern 164 in the vertical direction (e.g., the Z direction) may differ from length of the inner wall of the gate-side dielectric pattern 162 in the vertical direction (e.g., the Z direction), and in this case, the plurality of boundary dielectric patterns 160 may have a stepped structure. For example, a length of an outer wall of the charge trapping pattern 164 in the vertical direction (e.g., the Z direction) may be greater than a length of an inner wall of the gate-side dielectric pattern 162 in the vertical direction (e.g., the Z direction). For example, a length of an outer wall of the charge trapping pattern 164 in the vertical direction (e.g., the Z direction) may be less than a length of an inner wall of the gate-side dielectric pattern 162 in the vertical direction (e.g., the Z direction). In some embodiments, the average vertical length of the charge trapping pattern 164 in the horizontal direction may be substantially equal to the average vertical length of the gate-side dielectric pattern 162 in the horizontal direction, or may be less than the average vertical length of the gate-side dielectric pattern 162 in the horizontal direction. Accordingly, in the embodiments described above, a length of the charge trapping pattern 164 in the vertical direction (e.g., the Z direction) and a length of the gate-side dielectric pattern 162 in the vertical direction (e.g., the Z direction) may each increase progressively toward the ferroelectric layer 170.

FIG. 3, illustrates an example in which each of a length of the charge trapping pattern 164 in the vertical direction (e.g., the Z direction) and a length of the gate-side dielectric pattern 162 in the vertical direction (e.g., the Z direction) is less than a second height H2 of the gate line 130, but embodiments are not limited thereto. For example, a length of the outer wall of the charge trapping pattern 164 in the vertical direction (e.g., the Z direction) may be less than the second height H2, and each of the gate-side dielectric pattern 162 and/or the charge trapping pattern 164 may include a portion having a length in the vertical direction (e.g., the Z direction) is greater than or equal to the second height H2.

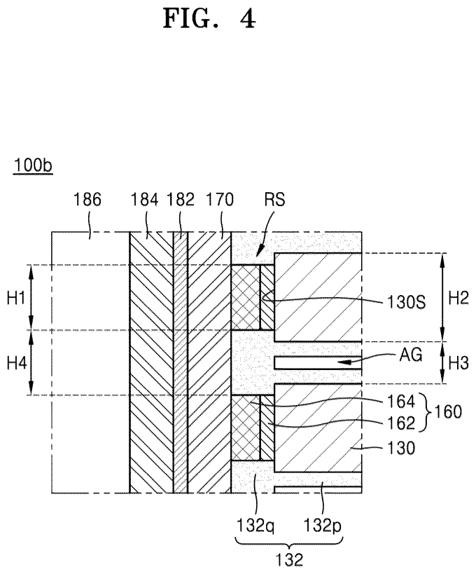

FIG. 4 is a cross-sectional view for describing a semiconductor device 100b according to embodiments. In FIG. 4, an enlarged cross-sectional configuration of a portion corresponding to the region EXA2 of FIG. 2C in the semiconductor device 100b is illustrated.

In FIG. 4, the same reference numerals as FIGS. 2A to 2E refer to like elements, and redundant or duplicative descriptions thereof may be omitted.

Referring to FIG. 4, the semiconductor device 100b may have substantially the same configuration as the semiconductor device 100 described above with reference to FIGS. 2A to 2E. In the semiconductor device 100b, a gap-fill insulation pattern 132 may include an air gap AG therein.

In some embodiments, the gap-fill insulation pattern 132 may be around (or for example may surround) the air gap AG, and the air gap AG may be apart from a plurality of gate lines 130, a ferroelectric layer 170, and a plurality of boundary dielectric patterns 160 with the gap-fill insulation pattern 132 therebetween.

In some embodiments, the air gap AG may at least partially and vertically overlap the plurality of gate lines 130. In some embodiments, the air gap AG may vertically overlap the plurality of boundary dielectric patterns 160, in the gap-fill insulation pattern 132. In some embodiments, the air gap AG may include a portion vertically overlapping the plurality of gate lines 130 and a portion vertically overlapping the plurality of boundary dielectric patterns 160.

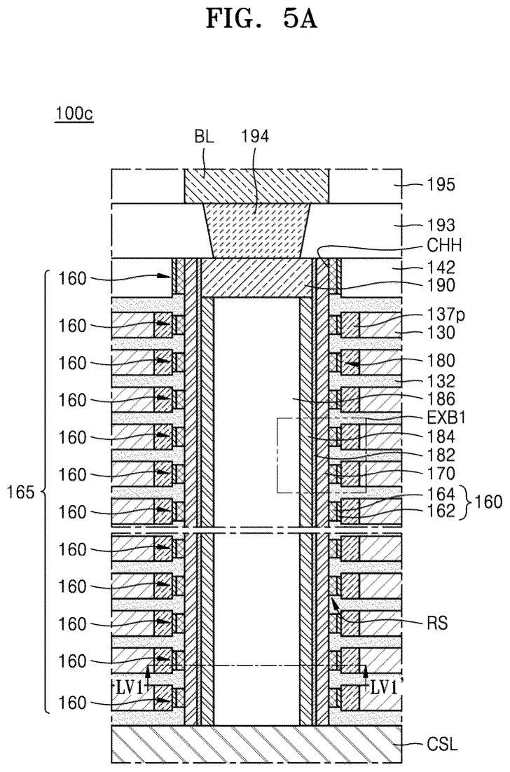

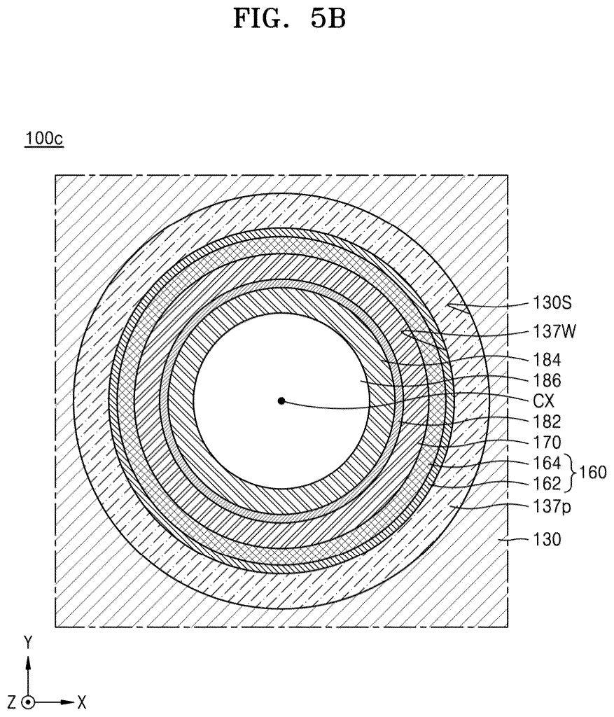

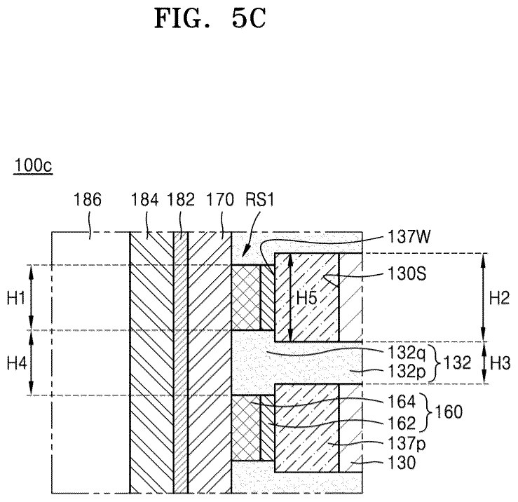

FIGS. 5A to 5C are diagrams for describing a semiconductor device 100c according to embodiments, FIG. 5A is an enlarged cross-sectional view of a portion, corresponding to the region EXA1 of FIG. 2B, of the semiconductor device 100c, FIG. 5B is an enlarged plan view of a partial region taken along line LV1-LV1′ of FIG. 5A, and FIG. 5C is an enlarged cross-sectional view of a region EXB1 of FIG. 5A. In FIGS. 5A to 5C, the same reference numerals as FIGS. 2A to 2E refer to like elements, and redundant or duplicative descriptions thereof may be omitted.

Referring to FIGS. 5A to 5C, the semiconductor device 100c may have substantially the same configuration as the semiconductor device 100 described above with reference to FIGS. 2A to 2E. The semiconductor device 100c may include a plurality of conductive patterns 137p each disposed between a channel structure 180 and a corresponding gate line 130 of the plurality of gate lines 130.

Referring to FIGS. 5A to 5C, each of the plurality of conductive patterns 137p may be disposed between a corresponding gate line 130 of the plurality of gate lines 130 and one boundary dielectric pattern 160 from among a plurality of boundary dielectric patterns 160. In some embodiments, each of the plurality of conductive patterns 137p may include an inner wall 137W on a corresponding boundary dielectric pattern 160 of the plurality of boundary dielectric patterns 160 and an outer wall on a sidewall 130S of the gate line 130.

In some embodiments, each of the plurality of conductive patterns 137p may have a ring shape around (or for example may surrounding) the channel structure 180, and in a plan view, a corresponding boundary dielectric pattern 160 of the plurality of boundary dielectric patterns 160, a ferroelectric layer 170, a channel-side dielectric layer 182, and a channel layer 184 may have a concentric circle shape.

In some embodiments, the gap-fill insulation pattern 132 may be disposed between the plurality of conductive patterns 137p apart from one another in a vertical direction (e.g., the Z direction).

In some embodiments, a fifth height H5, which may correspond to a length of each the plurality of conductive patterns 137p in the vertical direction (e.g., the Z direction), may be substantially the same as a second height H2, which may correspond to a length of each of the plurality of gate lines 130 in the vertical direction (e.g., the Z direction). For example, the fifth height H5 of each the plurality of conductive patterns 137p may be greater than a first height H1, which may correspond to a length of each of the plurality of boundary dielectric patterns 160 in the vertical direction (e.g., the Z direction).

In some embodiments, the fifth height H5 of each the plurality of conductive patterns 137p may be less than the second height H2 of each of the plurality of gate lines 130. However, in some embodiments, the fifth height H5 of each the plurality of conductive patterns 137p may be greater than the first height H1 of each of the plurality of boundary dielectric patterns 160.

In some embodiments, an inner wall 137W of each of the plurality of conductive patterns 137p may include a portion facing a corresponding boundary dielectric pattern 160 of the plurality of boundary dielectric patterns 160 in the horizontal direction (e.g., the X direction and/or the Y direction) and a portion facing the gap-fill insulation pattern 132. In some embodiments, the inner wall 137W of each of the plurality of conductive patterns 137p may include a portion facing an outer wall of a corresponding boundary dielectric pattern 160 of the plurality of boundary dielectric patterns 160 and a portion facing the gap-fill insulation pattern 132. In some embodiments, a recess RS1 may be defined by a portion of an outer wall of the ferroelectric layer 170, an upper surface of a first boundary dielectric pattern 160 of the plurality of dielectric patterns and a lower surface of a second boundary dielectric pattern 160 of the plurality of dielectric patterns facing the upper surface of the first boundary dielectric pattern 160, and a portion of the inner wall 137W of each of two conductive patterns 137p each on the first boundary dielectric pattern 160 and the second boundary dielectric pattern 160. In some embodiments, a plurality of recesses RS1 may be filled by the gap-fill insulation pattern 132.

In some embodiments, a plurality of first portions 132p of the gap-fill insulation pattern 132 may vertically overlap the plurality of gate lines 130 and the plurality of conductive patterns 137p, and a plurality of second portions 132q may vertically overlap the plurality of boundary insulation patterns 160. In some embodiments, a length of a portion which vertically overlaps the plurality of conductive patterns 137p of each of the plurality of first portions 132p in the vertical direction (e.g., the Z direction) may be less than a fourth height H4, which may correspond to a length of each of the plurality of second portions 132q in the vertical direction (e.g., the Z direction).

In some embodiments, the plurality of second portions 132q may include a portion on the ferroelectric layer 170, a portion on the plurality of boundary dielectric patterns 160, and a portion on a portion of the inner wall 137W of each of the plurality of conductive patterns 137p. For example, the inner wall 137W of each of the plurality of conductive patterns 137p may include a portion facing the ferroelectric layer 170 in the horizontal direction with a second portion 132q of the plurality of second portions 132q of the gap-fill insulation pattern 132 therebetween.

In some embodiments, the plurality of conductive patterns 137p may include a material which differs from a material of the plurality of gate lines 130. In some embodiments, the plurality of conductive patterns 137p may include tungsten, nickel, cobalt, tantalum, tungsten nitride, titanium nitride, tantalum nitride, doped polysilicon, tungsten silicide, nickel silicide, cobalt silicide, tantalum silicide, or a combination thereof, but embodiments are not limited thereto.

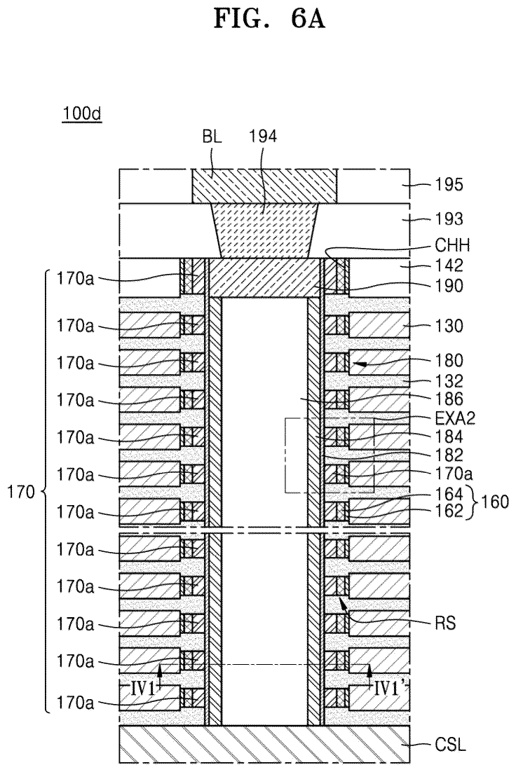

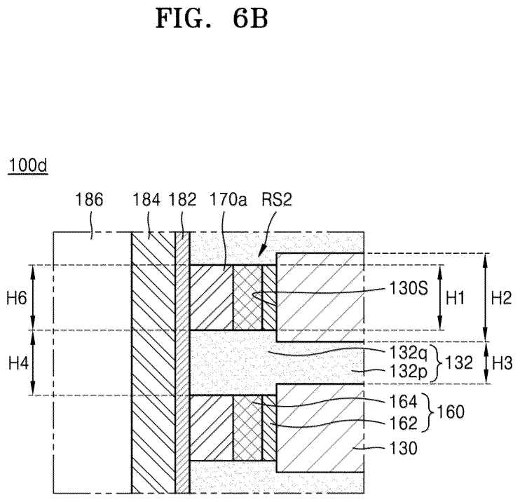

FIGS. 6A and 6B are cross-sectional views for describing a semiconductor device 100d according to embodiments. In FIG. 6A, an enlarged cross-sectional configuration of a region corresponding to the region EXA1 of FIG. 2B in the semiconductor device 100d is illustrated. FIG. 6B is an enlarged cross-sectional view of a region EXC1 of FIG. 6A. In FIGS. 6A and 6B, the same reference numerals as FIGS. 2A to 2E refer to like elements, and redundant or duplicative descriptions thereof may be omitted.

Referring to FIGS. 6A and 6B, the semiconductor device 100d may have substantially the same configuration as the semiconductor device 100 described above with reference to FIGS. 2A to 2E. A ferroelectric layer 170 of the semiconductor device 100d may include a plurality of ferroelectric patterns 170a which may be apart from one another in a vertical direction (e.g., the Z direction) and which may each be disposed between a channel-side dielectric layer 182 and a corresponding boundary dielectric pattern 160 of a plurality of boundary dielectric patterns 160.

In some embodiments, each of the plurality of ferroelectric patterns 170a may be disposed between the channel-side dielectric layer 182 and one boundary dielectric pattern 160 from among the plurality of boundary dielectric patterns 160. In some embodiments, an inner wall of each of the plurality of ferroelectric patterns 170a may be on the channel-side dielectric layer 182, and an outer wall thereof may be on an inner wall of a corresponding boundary dielectric pattern 160 of the plurality of boundary dielectric patterns 160. In some embodiments, the plurality of ferroelectric patterns 170a may be arranged in the vertical direction (e.g., the Z direction) to be around (or for example surround) an outer wall of the channel-side dielectric layer 182. In some embodiments, each of the plurality of ferroelectric patterns 170a may have a ring shape and in a plan view, may have a circular shape which shares a center CX with a corresponding boundary dielectric pattern 160 of the plurality of boundary dielectric patterns 160.

In some embodiments, a gap-fill insulation pattern 132 may be disposed between the plurality of ferroelectric patterns 170a apart from one another in the vertical direction (e.g., the Z direction). The plurality of ferroelectric patterns 170a may be apart from one another in the vertical direction (e.g., the Z direction) with a second portion 132q of the gap-fill insulation pattern 132. In some embodiments, the gap-fill insulation pattern 132 may be on the channel-side dielectric layer 182 with the plurality of ferroelectric patterns 170a therebetween. In some embodiments, the channel-side dielectric layer 182 may extend lengthwise in the vertical direction (e.g., the Z direction) in a space defined by the plurality of ferroelectric patterns 170a and the gap-fill insulation pattern 132.

In some embodiments, each of the plurality of ferroelectric patterns 170a may include a surface which faces the gap-fill insulation pattern 132 in the vertical direction (e.g., the Z direction). For example, each of an upper surface and a lower surface of each of the plurality of ferroelectric patterns 170a in the vertical direction (e.g., the Z direction) may be on the gap-fill insulation pattern 132.

In some embodiments, a recess RS2 may be defined by a portion of the outer wall of the channel-side dielectric layer 182, an upper surface of a first boundary dielectric pattern 160 of the plurality of dielectric patterns and a lower surface of a second boundary dielectric pattern 160 of the plurality of dielectric patterns facing the upper surface of the first boundary dielectric pattern 160, an upper surface of a first ferroelectric pattern 170a of the plurality of the plurality of ferroelectric patterns 170a, a lower surface of a second ferroelectric pattern 170a of the plurality of ferroelectric patterns 170a facing the upper surface of the first ferroelectric pattern 170a, and a portion of a sidewall 130S of each of a plurality of gate lines 130 each on the first boundary dielectric pattern 160 and the second boundary dielectric pattern 160. In some embodiments, a plurality of recesses RS2 may be filled by the gap-fill insulation pattern 132. The first boundary dielectric pattern 160 and the second dielectric pattern 160 may be apart from each other with the gap-fill insulation pattern 132 therebetween, and the first ferroelectric pattern 170a and the second ferroelectric pattern 170a may be apart from each other with the gap-fill insulation pattern 132 therebetween.

In some embodiments, a plurality of second portions 132q of the gap-fill insulation pattern 132 may each include a portion vertically overlapping the ferroelectric pattern 170a. Each of the plurality of second portions 132q of the gap-fill insulation pattern 132 may fill the recess RS2 at one side or both sides thereof in the vertical direction (e.g., the Z direction).

In some embodiments, a sixth height H6, which may correspond to a length of each of the plurality of ferroelectric patterns 170a in the vertical direction (e.g., the Z direction), may be less than a second height H2 of each of the plurality of gate lines 130. In some embodiments, the sixth height H6 of each of the plurality of ferroelectric patterns 170a may be substantially the same as a first height H1 of each of the plurality of boundary dielectric patterns 160.

In some embodiments, the sixth height H6 of each of the plurality of ferroelectric patterns 170a may differ from the first height H1 of each of the plurality of boundary dielectric patterns 160. For example, the sixth height H6 of each of the plurality of ferroelectric patterns 170a may be greater than the first height H1 of each of the plurality of boundary dielectric patterns 160. In some other embodiments, the sixth height H6 of each of the plurality of ferroelectric patterns 170a may be less than the first height H1 of each of the plurality of boundary dielectric patterns 160.

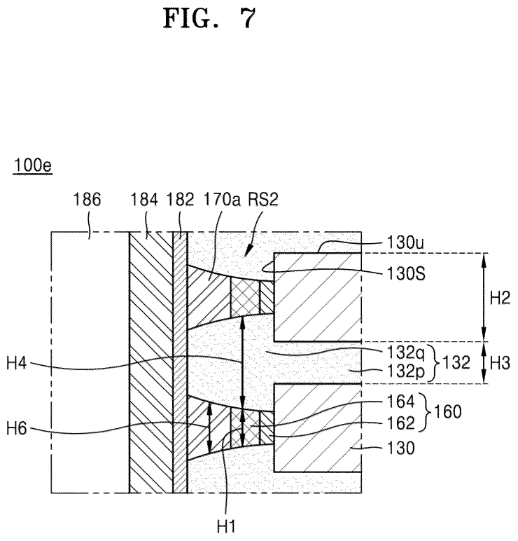

FIG. 7 is a cross-sectional view for describing a semiconductor device 100e according to embodiments. In FIG. 7, an enlarged cross-sectional configuration of a portion corresponding to the region EXA2 of FIG. 2C in the semiconductor device 100e is illustrated. In FIG. 7, the same reference numerals as FIGS. 2A to 2E, 3, and 7 refer to like elements, and redundant or duplicative descriptions thereof may be omitted.

Referring to FIG. 7, the semiconductor device 100e may have substantially the same configuration as the semiconductor device 100d described above with reference to FIG. 6. In the semiconductor device 100e, a surface facing a gap-fill insulation pattern 132 of each of a plurality of ferroelectric patterns 170a and a plurality of boundary dielectric patterns 160 may have a slope with respect to an upper surface 130u of a corresponding gate line 130 of a plurality of gate lines 130. Also, the semiconductor device 100e may have substantially the same configuration the semiconductor device 100a described above with reference to FIG. 3, and a ferroelectric layer 170 of the semiconductor device 100e may include the plurality of ferroelectric patterns 170a apart from one another in a vertical direction (e.g., the Z direction).

In some embodiments, each of an upper surface and a lower surface of each of the plurality of ferroelectric patterns 170a on a gap-fill insulation pattern 132 may have a slope with respect to the upper surface 130u of the gate line 130, and each of an upper surface and a lower surface of each of a plurality of boundary dielectric patterns 160 on the gap-fill insulation pattern 132 may have a slope with respect to the upper surface 130u of the gate line 130.

In some embodiments, a sixth height H6 of each of the plurality of ferroelectric patterns 170a may decrease progressively toward the plurality of gate lines 130. Accordingly, a first height H1 of each of the plurality of boundary dielectric patterns 160 may decrease progressively toward the plurality of gate lines 130. In some embodiments, the upper surface of each of the plurality of ferroelectric patterns 170a and the plurality of boundary dielectric patterns 160 may have a downward slope in a direction away from a channel-side dielectric layer 182, a vertical level of the upper surface of each of the plurality of ferroelectric patterns 170a and the plurality of boundary dielectric patterns 160 may be lower as the distance from the channel-side dielectric layer 182 increases.

In some embodiments, the lower surface of each of the plurality of ferroelectric patterns 170a and the plurality of boundary dielectric patterns 160 may have an upward slope in a direction away from the channel-side dielectric layer 182, and a vertical level of the lower surface of each of the plurality of ferroelectric patterns 170a and the plurality of boundary dielectric patterns 160 may be higher as the distance from the channel-side dielectric layer 182 increases. In some embodiments, the upper surface and the lower surface of each of the plurality of ferroelectric patterns 170a and the plurality of boundary dielectric patterns 160 may have a curved shape.

In some embodiments, a fourth height H4, which may correspond to a length of each of a plurality of second portions 132q of the gap-fill insulation pattern 132 in the vertical direction (e.g., the Z direction), may decrease progressively toward the ferroelectric layer 170. For example, each of the upper surface and the lower surface of each of the plurality of second portions 132q of the gap-fill insulation pattern 132 may have a slope with respect to the upper surface 130u of the gate line 130. In some embodiments, for example, each of the upper surface and the lower surface of each of the plurality of second portions 132q of the gap-fill insulation pattern 132 may have a curved shape.

FIG. 7 illustrates an example in which a length of each of the plurality of ferroelectric patterns 170a in the vertical direction (e.g., the Z direction) is the same as that of an inner wall of each of the plurality of boundary dielectric patterns 160 in the vertical direction (e.g., the Z direction), and an average of sixth heights H6 of the plurality of ferroelectric patterns 170a in a horizontal direction is greater than an average of first heights H1 of the plurality of boundary dielectric patterns 160 in the horizontal direction, but embodiments are not limited thereto. In some embodiments, a length of an outer wall of each of the plurality of ferroelectric patterns 170a in the vertical direction (e.g., the Z direction) may differ from a length of the inner wall of each of the plurality of boundary dielectric patterns 160 in the vertical direction (e.g., the Z direction), and in this case, each of a plurality of second portions 132q of the gap-fill insulation pattern 132 may have a stepped structure. In some embodiments, an average of the sixth heights H6 of the plurality of ferroelectric patterns 170a in the horizontal direction may be less than or equal to an average of the first heights H1 of the plurality of boundary dielectric patterns 160 in the horizontal direction. Furthermore, in the embodiments described above, the sixth height H6 of each of the plurality of ferroelectric patterns 170a may increase progressively toward a channel layer 184, and the first height H1 of each of the plurality of boundary dielectric patterns 160 may increase progressively toward the channel layer 184.

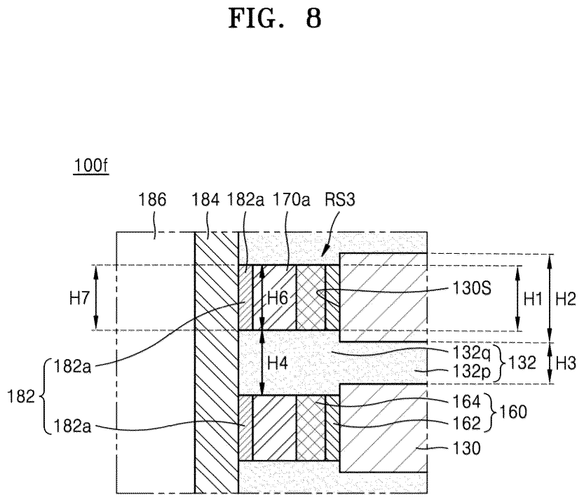

FIG. 8 is a cross-sectional view for describing a semiconductor device 100f according to embodiments. In FIG. 8, an enlarged cross-sectional configuration of a region corresponding to the region EXA2 of FIG. 2C in the semiconductor device 100f is illustrated. In FIG. 8, the same reference numerals as FIGS. 2A to 2E, 6A, and 6B refer to like elements, and redundant or duplicative descriptions thereof may be omitted.

Referring to FIG. 8, the semiconductor device 100f may have substantially the same configuration as the semiconductor device 100d described above with reference to FIGS. 6A and 6B. A channel-side dielectric layer 182 of the semiconductor device 100f may include a plurality of channel-side dielectric patterns 182a which may be apart from one another in a vertical direction (e.g., the Z direction) and which may each be disposed between a channel layer 184 and a corresponding ferroelectric pattern 170a of a plurality of ferroelectric patterns 170a.

In some embodiments, each of the plurality of channel-side dielectric patterns 182a may be disposed between the channel layer 184 and one ferroelectric pattern 170a from among the plurality of ferroelectric patterns 170a. In some embodiments, an inner wall of each of the plurality of channel-side dielectric patterns 182a may be on the channel layer 184, and an outer wall thereof may be on an inner wall of a corresponding ferroelectric pattern 170a of the plurality of ferroelectric patterns 170a. In some embodiments, the plurality of channel-side dielectric patterns 182a may be arranged apart from one another in the vertical direction (e.g., the Z direction) to be around (or for example surround) an outer wall of the channel layer 184. In some embodiments, each of the plurality of channel-side dielectric patterns 182a may have a ring shape and in a plan view, may have a circular shape which shares a center CX with a corresponding ferroelectric pattern 170a of the plurality of ferroelectric patterns 170a.

In some embodiments, a gap-fill insulation pattern 132 may be disposed between the plurality of channel-side dielectric patterns 182a apart from one another in the vertical direction (e.g., the Z direction). In some embodiments, a second portion 132q of the gap-fill insulation pattern 132 may include a portion disposed between the plurality of channel-side dielectric patterns 182a. In some embodiments, the gap-fill insulation pattern 132 may be on an outer wall of the channel layer 184, between the plurality of channel-side dielectric patterns 182a. In some embodiments, the channel layer 184 may extend lengthwise in the vertical direction (e.g., the Z direction) in a space defined by the plurality of channel-side dielectric patterns 182a and the gap-fill insulation pattern 132.

In some embodiments, each of the plurality of channel-side dielectric patterns 182a may include a surface which faces the gap-fill insulation pattern 132 in the vertical direction (e.g., the Z direction). In some embodiments, an upper surface and a lower surface of each of the plurality of channel-side dielectric patterns 182a may be on the gap-fill insulation pattern 132.

In some embodiments, a recess RS3 may be defined by a portion of the outer wall of the channel layer 184, the upper surface and the lower surface of each of the plurality of channel-side dielectric patterns 182a, an upper surface and a lower surface of each of a plurality of boundary dielectric patterns 160, and a portion of a sidewall 130S of each of a plurality of gate lines 130, and a plurality of recesses RS3 may be filled by the gap-fill insulation pattern 132.

In some embodiments, a seventh height H7 which may correspond to a length of each of the plurality of channel-side dielectric patterns 182a in the vertical direction (e.g., the Z direction) may be less than a second height H2 of each of the plurality of gate lines 130. In some embodiments, the seventh height H7 of each of the plurality of channel-side dielectric patterns 182a may be substantially the same as a sixth height H6 of each of the plurality of ferroelectric patterns 170a and a first height H1 of each of the plurality of boundary dielectric patterns 160.

In some other embodiments, the seventh height H7 of each of the plurality of channel-side dielectric patterns 182a may differ from the sixth height H6 of each of the plurality of ferroelectric patterns 170a and the first height H1 of each of the plurality of boundary dielectric patterns 160.

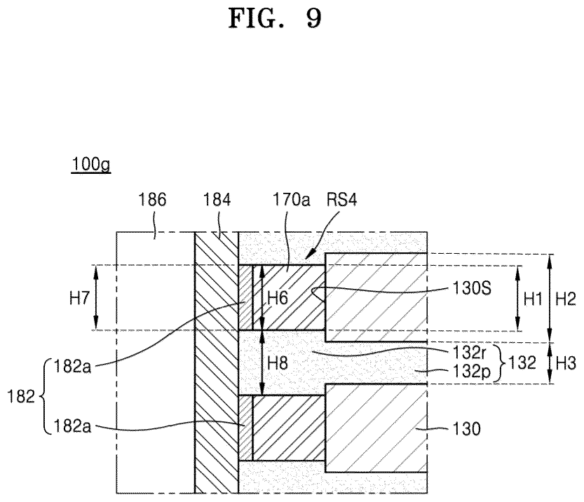

FIG. 9 is a cross-sectional view for describing a semiconductor device 100g according to embodiments. In FIG. 9, an enlarged cross-sectional configuration of a portion corresponding to the region EXA2 of FIG. 2C in the semiconductor device 100g is illustrated. In FIG. 9, the same reference numerals as FIGS. 2A to 2E, 6A, 6B, and 8 refer to like elements, and redundant or duplicative descriptions thereof may be omitted.

Referring to FIG. 9, the semiconductor device 100g may have substantially the same configuration as the semiconductor device 100f described above with reference to FIG. 8. In the semiconductor device 100g, a plurality of ferroelectric patterns 170a may respectively be on a plurality of gate lines 130. For example, the plurality of boundary dielectric patterns 160 in the semiconductor device 100g may be omitted.

In some embodiments, a channel structure 180 of the semiconductor device 100g may include a ferroelectric layer 170, a channel-side dielectric layer 182, a channel layer 184, and an insulation plug 186, which may be sequentially stacked in a direction toward a center CX (as shown for example in FIG. 2D) in the plurality of gate lines 130. In some embodiments, the channel-side dielectric layer 182 may include a plurality of channel-side dielectric patterns 182a apart from one another in a vertical direction (e.g., the Z direction), and the ferroelectric layer 170 may include a plurality of ferroelectric patterns 170a each disposed between a corresponding channel-side dielectric pattern 182a of the plurality of channel-side dielectric patterns 182a and a corresponding gate line 130 of the plurality of gate lines 130.

In some embodiments, the plurality of ferroelectric patterns 170a may be apart from one another in the vertical direction (e.g., the Z direction), and each of the plurality of ferroelectric patterns 170a may be on one gate line 130 from among the plurality of gate lines 130. In some embodiments, an inner wall of each of the plurality of ferroelectric patterns 170a may be on an outer wall of a corresponding channel-side dielectric pattern 182a of the plurality of channel-side dielectric patterns 182a, and an outer wall of each of the plurality of ferroelectric patterns 170a may be on a sidewall 130S of a corresponding gate line 130 of the plurality of gate lines 130. In some embodiments, the channel layer 184 may extend lengthwise in the vertical direction (e.g., the Z direction) in a space defined by the plurality of channel-side dielectric patterns 182a and the gap-fill insulation pattern 132.

In some embodiments, the gap-fill insulation pattern 132 may fill a space between the plurality of gate lines 130, a space between the plurality of ferroelectric patterns 170a, and a space between the plurality of channel-side dielectric patterns 182a. In some embodiments, the gap-fill insulation pattern 132 may be on an outer wall of the channel layer 184, in the space between the plurality of channel-side dielectric patterns 182a. In some embodiments, each of the plurality of channel-side dielectric patterns 182a and the plurality of ferroelectric patterns 170a may include a surface facing the gap-fill insulation pattern 132 in the vertical direction (e.g., the Z direction).

A relationship between a second height H2 of each of the plurality of gate lines 130, a third height H3 of each of the plurality of ferroelectric patterns 170a, and a sixth height H6 of each of the plurality of ferroelectric patterns 170a may be substantially the same as the semiconductor device 100f described above with reference to FIG. 8. For example, the third height H3 of each of the plurality of ferroelectric patterns 170a and the sixth height H6 of each of the plurality of ferroelectric patterns 170a may be less than the second height H2 of each of the plurality of gate lines 130.

In some embodiments, a recess RS4 may be defined by a portion of the outer wall of the channel layer 184, an upper surface and a lower surface of each of the plurality of channel-side dielectric patterns 182a, an upper surface and a lower surface of each of the plurality of ferroelectric patterns 170a, and a portion of a sidewall 130S of each of the plurality of gate lines 130, and a plurality of recesses RS4 may be filled by the gap-fill insulation pattern 132. In some embodiments, a sidewall of the gate line 130 may include a portion on the gap-fill insulation pattern 132 and a portion on a corresponding ferroelectric pattern 170a of the plurality of ferroelectric patterns 170a.

In some embodiments, the gap-fill insulation pattern 132 of the semiconductor device 100g may include a plurality of first portions 130p vertically overlapping the plurality of gate lines 130 and a plurality of third portions 130r extending from the plurality of first portions 130q and vertically overlapping the plurality of channel-side dielectric patterns 182a and the plurality of ferroelectric patterns 170a. In some embodiments, the plurality of third portions 130r may fill the plurality of recesses RS4 and may be on an outer wall of the channel layer 184. In some embodiments, an eighth height H8 which may correspond to a length of each of the plurality of third portions 130r in the vertical direction (e.g., the Z direction) may be greater than a third height H3 of each of the plurality of first portions 130p.

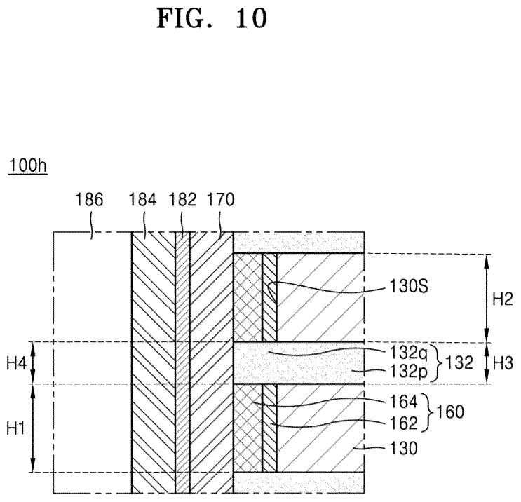

FIG. 10 is a cross-sectional view for describing a semiconductor device 100h according to embodiments. In FIG. 10, an enlarged cross-sectional configuration of a portion corresponding to the region EXA2 of FIG. 2C in the semiconductor device 100h is illustrated. In FIG. 10, the same reference numerals as FIGS. 2A to 2E refer to like elements, and redundant or duplicative descriptions thereof may be omitted.

Referring to FIG. 10, the semiconductor device 100h may have substantially the same configuration as the semiconductor device 100 described above with reference to FIGS. 2A to 2E. In the semiconductor device 100h, a first height H1 of each of a plurality of boundary dielectric patterns 160 may be substantially the same as a second height H2 of each of a plurality of gate lines 130.

In some embodiments, the semiconductor device 100h may not include the plurality of recesses RS2 of the semiconductor device 100 described above with reference to FIGS. 2A to 2E. In some embodiments, the first height H1 of each of the plurality of boundary dielectric patterns 160 may be substantially the same as the second height H2 of each of a plurality of gate lines 130. A third height H3 of each of the plurality of first portions 132p of the gap-fill insulation pattern 132 may be substantially the same as a fourth height H4 of each of the plurality of second portions 132q. In some embodiments, the sidewall 130S of each of the plurality of gate lines 130 may be entirely on an outer wall of each of the plurality of boundary dielectric patterns 160 and may not include a portion on the gap-fill insulation pattern 132.

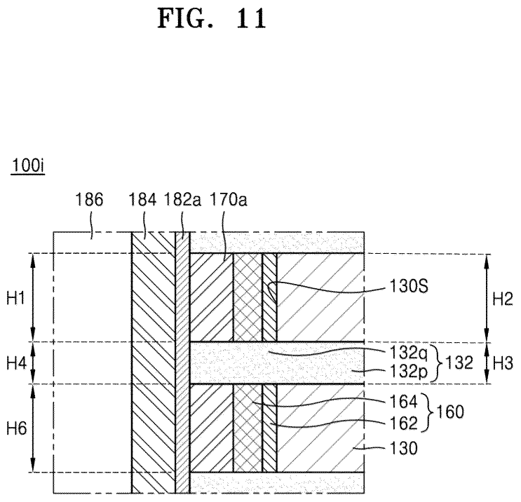

FIG. 11 is a cross-sectional view for describing a semiconductor device 100i according to embodiments. In FIG. 11, an enlarged cross-sectional configuration of a portion corresponding to the region EXA2 of FIG. 2C in the semiconductor device 100i is illustrated. In FIG. 11, the same reference numerals as FIGS. 2A to 2E, 6A, and 6B refer to like elements, and redundant or duplicative descriptions thereof may be omitted.

Referring to FIG. 11, the semiconductor device 100i may have substantially the same configuration as the semiconductor device 100d described above with reference to FIGS. 6A and 6B. In the semiconductor device 100i, a first height H1 of each of a plurality of boundary dielectric patterns 160 may be substantially the same as a second height H2 of each of a plurality of gate lines 130, and a sixth height H6 of each of a plurality of ferroelectric patterns 170a may be substantially the same as the second height H2.

In some embodiments, the semiconductor device 100i may not include the plurality of recesses RS2 of the semiconductor device 100d described above with reference to FIGS. 6A and 6B. In some embodiments, the first height H1 of each of the plurality of boundary dielectric patterns 160 may be substantially the same as the second height H2 of each of the plurality of gate lines 130, and the sixth height H6 of each of the plurality of ferroelectric patterns 170a may be substantially the same as the second height H2. In some embodiments, a third height H3 of each of the plurality of first portions 132p of the gap-fill insulation pattern 132 may be substantially the same as a fourth height H4 of each of the plurality of second portions 132q. In some embodiments, the sidewall 130S of each of the plurality of gate lines 130 may entirely be on an outer wall of each of the plurality of boundary dielectric patterns 160 and may not include a portion on the gap-fill insulation pattern 132.

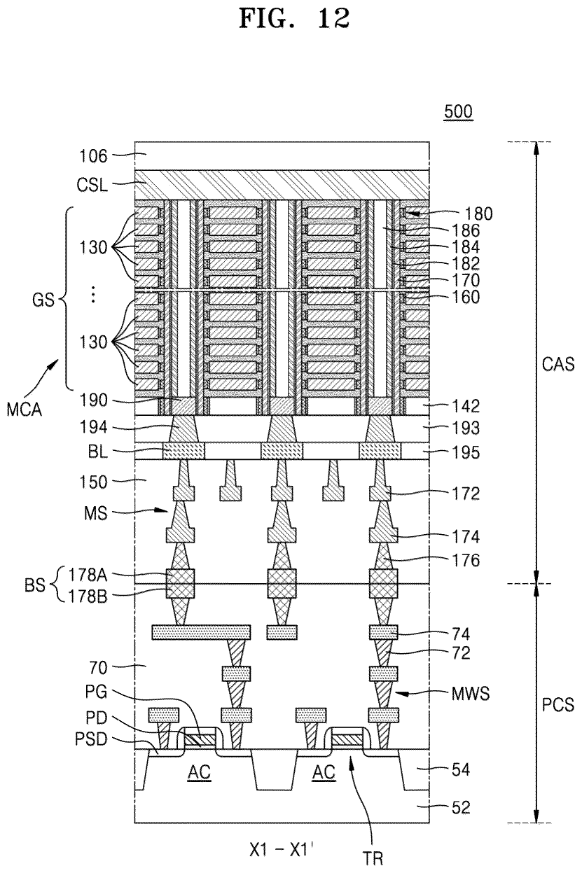

FIG. 12 is a cross-sectional view for describing a semiconductor device 500 according to embodiments. In FIG. 12, the same reference numerals as FIGS. 2A to 2E refer to like elements, and redundant or duplicative descriptions thereof may be omitted.

Referring to FIG. 12, the semiconductor device 500 may include a cell array structure CAS and a peripheral circuit structure PCS, which overlap each other in a vertical direction (e.g., the Z direction). The cell array structure CAS may include a memory cell region MEC where a memory cell array MCA is disposed.

In embodiments, the semiconductor device 500 may have a chip to chip (C2C) structure. The cell array structure CAS may be formed on a first wafer, the peripheral circuit structure PCS may be formed on a second wafer which differs from the first wafer, and the cell array structure CAS may be connected to the peripheral circuit structure PCS through a bonding process, thereby obtaining the C2C structure. For example, the bonding process may refer to a process of bonding a first bonding metal pad 178A, formed in an uppermost metal layer of the cell array structure CAS, to a second bonding metal pad 178B formed in an uppermost metal layer of the peripheral circuit structure PCS so as to enable an electrical connection therebetween. In some embodiments, when the first bonding metal pad 178A and the second bonding metal pad 178B include copper (Cu), the bonding process may referred to as a Cu—Cu bonding process. In some other embodiments, each of the first bonding metal pad 178A and the second bonding metal pad 178B may include aluminum (Al) or tungsten (W).

A gate stack GS including a plurality of gate lines 130 included in the memory cell array MCA may be disposed between a common source line CSL and a peripheral circuit structure PCS.

The peripheral circuit structure PCS may include a substrate 52, a plurality of circuits formed on the substrate 52, and a multi-layer wiring structure MWS for connecting the plurality of circuits with each other or connecting the plurality of circuits to elements provided in the memory cell region MEC of the cell array structure CAS.

The substrate 52 may include a semiconductor substrate. For example, the substrate 52 may include silicon (Si), germanium (Ge), or silicon germanium (SiGe). An active region AC may be defined in the substrate 52 by a device isolation layer 54. A plurality of transistors TR configuring the plurality of circuits may be formed on the active region AC. Each of the plurality of transistors TR may include a gate dielectric layer PD and a gate PG, sequentially stacked on the substrate 52, and a plurality of ion implantation regions PSD formed in the active region ACT at both sides of the gate PG. Each of the plurality of ion implantation regions PSD may configure a source region or a drain region of the transistor TR.

The multi-layer wiring structure MWS included in the peripheral circuit structure PCS may include a plurality of contact plugs 72 and a plurality of conductive lines 74. At least some of the plurality of conductive lines 74 may be configured to be electrically connected to the transistor TR. The plurality of contact plugs 72 may be configured to connect some from among the plurality of conductive lines 74 and the plurality of transistors TR with each other. The plurality of transistors TR and the multi-layer wiring structure MWS each included in the peripheral circuit structure PCS may be partially or entirely covered by an interlayer insulation layer 70. The interlayer insulation layer 70 may include a silicon oxide layer, a silicon nitride layer, a SiON layer, a SiOCN layer, or a combination thereof.

The plurality of circuits included in the peripheral circuit structure PCS may include various circuits included in the peripheral circuit 30 described above with reference to FIG. 1. In embodiments, the peripheral circuit structure PCS may further include unit elements such as a resistor and a capacitor. The plurality of transistors TR, the plurality of contact plugs 72, and the plurality of conductive lines 74 each included in the peripheral circuit structure PCS may configure the plurality of circuits. The plurality of transistors TR may be configured to be electrically connected to the memory cell region MEC through the plurality of multi-layer wiring structures MWS, respectively. The common source line CSL included in the cell array structure CAS may be apart from the peripheral circuit structure PCS in the vertical direction (e.g., the Z direction) with the memory cell region MEC therebetween.

Each of a plurality of bit lines BL may be connected to a wiring structure MS. The wiring structure MS may include a first upper wiring layer 172, a second upper wiring layer 174, and a third upper wiring layer 176. Each of the first upper wiring layer 172, the second upper wiring layer 174, and the third upper wiring layer 176 may include tungsten, titanium, tantalum, copper, aluminum, titanium nitride, tantalum nitride, tungsten nitride, or a combination thereof.

A plurality of first bonding metal pads 178A may be disposed on an upper surface, which may be adjacent to the peripheral circuit structure PCS, of the cell array structure CAS. The plurality of bit lines BL may be configured to be connected to the plurality of first bonding metal pads 178A through the wiring structure MS. Each of the plurality of first bonding metal pads 178A and the wiring structure MS in the cell array structure CAS may be partially or entirely covered by the interlayer insulation layer 70. The interlayer insulation layer 70 may include silicon oxide, silicon nitride, or a combination thereof.

The peripheral circuit structure PCS may be apart from a plurality of channel structures 180 with the plurality of bit lines BL therebetween. The peripheral circuit structure PCS may include a plurality of second bonding metal pads 178B disposed on the multi-layer wiring structure MWS. The plurality of second bonding metal pads 178B may be configured to be connected to the plurality of circuits included in the peripheral circuit structure PCS. In the peripheral circuit structure PCS, the interlayer insulation layer 70 may be on (or for example cover) the plurality of transistors TR, the plurality of conductive plugs 72, the plurality of conductive lines 74, and the plurality of second bonding metal pads 178B.

The plurality of second bonding metal pads 178B may be bonded to the plurality of first bonding metal pads 178A included in the cell array structure CAS and may be electrically connected to the plurality of first bonding metal pads 178A. The plurality of first bonding metal pads 178A and the plurality of second bonding metal pads 178B be included in a plurality of bonding structures BS. The plurality of bit lines BL may be configured to be connected to at least one circuit from among the plurality of circuits included in the peripheral circuit structure PCS through the bonding structure BS including the first bonding metal pad 178A and the second bonding metal pad 178B.

In some embodiments, each of the plurality of conductive plugs 72 and the plurality of conductive lines 74 in the peripheral circuit structure PCS may include tungsten, aluminum, copper, or a combination thereof, but embodiments are not limited thereto. The device isolation layer 54 may include silicon oxide, silicon nitride, or a combination thereof. The interlayer insulation layer 70 may include silicon oxide, silicon nitride, or a combination thereof. Each of the plurality of first bonding metal pads 178A and the plurality of second bonding metal pads 178B each configuring the plurality of bonding structures BS may include copper, aluminum, or tungsten.

In the cell array structure CAS, the common source line CSL may be partially or entirely covered by an insulation layer 106. The insulation layer 106 may include silicon oxide. Although not shown, the insulation layer 106 may be partially or entirely covered by a protection layer. The protection layer may include a polyimide-based material layer such as photosensitive polyimide (PSPI), but embodiments are not limited thereto.

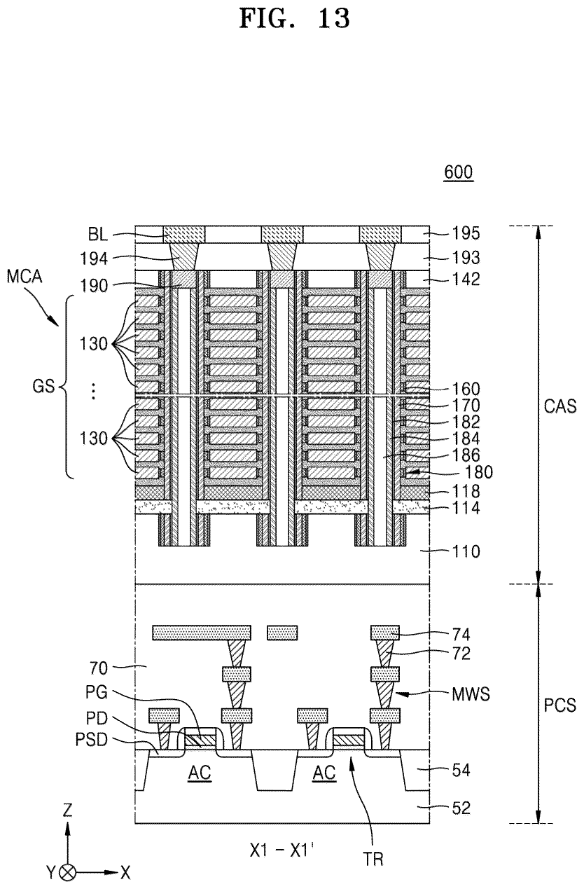

FIG. 13 is a cross-sectional view for describing a semiconductor device 600 according to embodiments. In FIG. 13, the same reference numerals as FIGS. 2A to 2E and 12 refer to like elements, and redundant or duplicative descriptions thereof may be omitted.

Referring to FIG. 13, the semiconductor device 600 may have substantially the same configuration as the semiconductor device 500 described above with reference to FIG. 12. The cell array structure CAS of the semiconductor device 600 may include a cell substrate 110 disposed on a peripheral circuit structure PCS and a gate stack GS disposed on the cell substrate 110.

In the cell array structure CAS, a first conductive plate 114 and a second conductive plate 118 may be sequentially disposed on the cell substrate 110, and the gate stack GS including a plurality of gate lines 130 may be disposed on the second conductive plate 118.

The cell substrate 110, the first conductive plate 114, and the second conductive plate 118 may perform a function of a common source line CSL (as shown for example in FIG. 1) which may transfer a current to vertical memory cells included in the cell array structure CAS.

In embodiments, the cell substrate 110 may include a semiconductor material such as doped polysilicon. Each of the first conductive plate 114 and the second conductive plate 118 may include a doped polysilicon layer, a metal layer, or a combination thereof. The metal layer may include tungsten (W), but embodiments are not limited thereto. An insulation pattern 132 may be disposed between the second conductive plate 118 and the plurality of gate lines 130 and between two adjacent gate lines 130 of the plurality of gate lines 130.

In the semiconductor device 600, the peripheral circuit structure PCS may be apart from a bit line BL with the plurality of gate lines 130 therebetween. The cell substrate 110 may be disposed between the peripheral circuit structure PCS and the first conductive plate 114. A plurality of channel structures 180 may pass through the second conductive plate 118 in a vertical direction (e.g., the Z direction), pass through a portion of the cell substrate 110 in the vertical direction (e.g., the Z direction), and extend lengthwise in the vertical direction (e.g., the Z direction). A channel layer 166 and an insulation plug 168 of each of the plurality of channel structures 180 may pass through the first conductive plate 114 and the second conductive plate 118 in the vertical direction (e.g., the Z direction), pass through a portion of the cell substrate 110 in the vertical direction (e.g., the Z direction), and extend lengthwise in the vertical direction (e.g., the Z direction). The first conductive plate 114 may pass through a ferroelectric layer 170 and a channel-side dielectric layer 182 in a horizontal direction and may be on a sidewall of the channel layer 166.

Hereinafter, a method of manufacturing a semiconductor device according to embodiments will be described in detail.

FIGS. 14A to 14F are cross-sectional views illustrating in process sequence a method of manufacturing a semiconductor device, according to embodiments. In FIGS. 14A to 14F, an enlarged cross-sectional configuration, based on a process sequence, of a region corresponding to the region EXA1 of FIG. 2B is illustrated. A method of manufacturing the semiconductor device 100 illustrated in FIGS. 2A to 2E may be described with reference to FIGS. 14A to 14F. In FIGS. FIGS. 14A to 14F, the same reference numerals as FIGS. 2A to 2E refer to like elements, and redundant or duplicative descriptions thereof may be omitted.

Referring to FIG. 14A, a plurality of sacrificial insulation layers and a plurality of conductive layers may be alternatingly stacked one-by-one on a sacrificial substrate 810, and then a middle insulation layer 142 may be formed on an uppermost sacrificial insulation layer of the plurality of sacrificial insulation layers. Subsequently, a vertical hole CHH passing through the plurality of sacrificial insulation layers, the plurality of conductive layers, and the middle insulation layer 142 and extending in the vertical direction (e.g., the Z direction) may be formed, and thus, a plurality of sacrificial insulation patterns 131 and a plurality of gate lines 130 each defining the vertical hole CHH may be formed. The vertical hole CHH may be formed to pass through a portion of the sacrificial substrate 810.

The sacrificial substrate 810 may include silicon. The plurality of sacrificial insulation patterns 131 may include silicon oxide, and the plurality of gate lines 130 may include doped polysilicon, but embodiments are not limited thereto. Each of the plurality of sacrificial insulation patterns 131 may secure a space for forming a gap-fill insulation pattern 132 (as shown for example in FIGS. 2B, 2C, and 2E) in a post-processing operation.

Referring to FIG. 14B, a preliminary boundary dielectric layer p165, a ferroelectric layer 170, a channel-side dielectric layer 182, and a channel layer 184 sequentially stacked on surfaces exposed at the inside and outside of the vertical hole CHH in a resultant material of FIG. 14A may be formed. The preliminary boundary dielectric layer p165 may include a gate-side dielectric layer p162, (or for example covering) an inner wall of the vertical hole CHH and an upper surface of the middle insulation layer 142, and a charge trapping layer p164 on the gate-side dielectric layer p162. In some embodiments, an outer wall of the gate-side dielectric layer p162 may be on sidewalls 130S of the plurality of gate lines 130 (as shown for example in FIG. 2E) defining the vertical hole CHH.

In some embodiments, an atomic layer deposition (ALD) process, a chemical vapor deposition (CVD) process, or a combination thereof may be used to form the preliminary boundary dielectric layer p165, the ferroelectric layer 170, the channel-side dielectric layer 182, and the channel layer 184, but embodiments are not limited to the above embodiments.

Referring to FIG. 14C, an insulation plug 186 filling an inner portion of the vertical hole CHH remaining on the channel layer 184 in a resultant material of FIG. 14B may be formed, and an upper surface of the middle insulation layer 142 may be exposed by planarizing an obtained resultant material. An ALD or CVD process may be used to form the insulation plug 186. A chemical mechanical polishing (CMP) process may be used for the planarization.

Referring to FIG. 14D, a plurality of insulation spaces RR exposing an outer wall of the preliminary boundary dielectric layer p165 may be formed by removing the plurality of sacrificial insulation patterns 131 in a resultant material of FIG. 14C.

To form the plurality of insulation spaces RR, the plurality of word line cut regions WLC described above with reference to FIG. 2A may be previously formed, and the plurality of sacrificial insulation patterns 131 may be removed through the plurality of word line cut regions WLC. For example, a wet etching process may be used for removing the plurality of sacrificial insulation patterns 131. After the plurality of sacrificial insulation patterns 131 are removed, a portion of an outer wall of the gate-side dielectric layer p162 may be exposed through the plurality of insulation spaces RR. The plurality of gate lines 130 may be apart from one another in the vertical direction (e.g., the Z direction) with one of the plurality of insulation spaces RR between two adjacent gate lines 130 of the plurality of gate lines 130.

Subsequently, a plurality of recesses RS exposing an outer wall of the ferroelectric layer 170 may be formed by removing a portion of the gate-side dielectric layer p162 and a portion of the charge trapping layer p164 through the plurality of insulation spaces RR. According to embodiments, a plurality of boundary dielectric patterns 160 apart from one another in the vertical direction (e.g., the Z direction) may be formed by the plurality of recesses RS. For example, a plurality of gate-side dielectric patterns 162 and a plurality of charge trapping patterns 164 may be formed by removing a portion of the gate-side dielectric layer p162 and a portion of the charge trapping layer p164.

According to embodiments, a dry etching process, a wet etching process, or a combination thereof may be used to form the plurality of recesses RS. In an etching process, the ferroelectric layer 170 and the plurality of gate lines 130 may have an etch selectivity with respect to the gate-side dielectric layer p162 and the charge trapping layer p164. According to embodiments, an isotropic etching process may be used to form the plurality of recesses RS, and a portion, which may be adjacent to an upper surface and a lower surface of the gate line 130, of the sidewall 130S of each of the plurality of gate lines 130 (as shown for example in FIG. 2E) may be exposed. For example, a vertical length of an outer wall of each of the plurality of boundary dielectric patterns 160 may be formed to be shorter than a vertical length of the sidewall 130S of each of the plurality of gate lines 130.

In some embodiments, a shape of each of the plurality of recesses RS may be changed based on the kind of material included in the gate-side dielectric layer p162 and the charge trapping layer p164, a thickness of each of the gate-side dielectric layer p162 and the charge trapping layer p164 in a horizontal direction, and the kind of etching gas used. For example, a length of each of the plurality of recesses RS in the vertical direction (e.g., the Z direction) may be formed to decrease progressively as a distance from the plurality of gate lines 130 in the horizontal direction increases. For example, a length of each of the plurality of boundary dielectric patterns 160 in the vertical direction (e.g., the Z direction) may decrease progressively as a distance from a center CX thereof (as shown for example in FIG. 2D) increases. In this case, the semiconductor device 100a described above with reference to FIG. 3 may be formed by using the same process as a manufacturing method described below.

In some embodiments, a plurality of recesses R2 (as shown for example in FIGS. 6A, 6B, and 7) exposing the channel-side dielectric layer 182 may be formed by removing a portion of the gate-side dielectric layer p162, a portion of the charge trapping layer p164, and a portion of the ferroelectric layer 170 through the plurality of insulation spaces RR. In an etching process of forming the plurality of recesses RS2, a portion of the ferroelectric layer 170 may be removed and may thus be divided into a plurality of ferroelectric patterns 170a. In this case, the semiconductor device 100d described above with reference to FIGS. 6A and 6B or the semiconductor device 100e described above with reference to FIG. 7 may be formed by using the same process as a manufacturing method described below.

In some embodiments, a plurality of recesses R3 (as shown for example in FIG. 8) exposing the channel layer 184 may be formed by removing a portion of the gate-side dielectric layer p162, a portion of the charge trapping layer p164, a portion of the ferroelectric layer 170, and a portion of the channel-side dielectric layer 182 through the plurality of insulation spaces RR. In an etching process of forming the plurality of recesses RS3, a portion of the ferroelectric layer 170 may be removed and may thus be divided into the plurality of ferroelectric patterns 170a, and a portion of the channel-side dielectric layer 182 may be removed and may thus be divided into a plurality of channel-side dielectric patterns 182a. In this case, the semiconductor device 100f described above with reference to FIG. 8 may be formed by using the same process as a manufacturing method described below.

In some embodiments, in the method of manufacturing the semiconductor device described above with reference to FIGS. 14A and 14B, the boundary dielectric layer p165 may be omitted, and the ferroelectric layer 170 on an inner wall of the vertical hole CHH and an upper surface of the middle insulation layer 142, the channel-side dielectric layer 182 on the ferroelectric layer 170, and the channel layer 184 on the channel-side dielectric layer 182 may be sequentially formed. Subsequently, as described above with reference to FIG. 14C, after the insulation plug 186 is formed, a plurality of insulation spaces RR may be formed by removing the plurality of sacrificial insulation patterns 131, and a plurality of recesses R4 (as shown for example in FIG. 9) exposing the channel layer 184 may be formed by removing a portion of the ferroelectric layer 170 and a portion of the channel-side dielectric layer 182 through the plurality of insulation spaces RR. In this case, the semiconductor device 100g described above with reference to FIG. 9 may be formed by using the same process as a manufacturing method described below.

Referring again to FIG. 14D in conjunction with FIG. 14E, a gap-fill insulation pattern 132 filling the plurality of insulation spaces RR and the plurality of recesses RS may be formed. In some embodiments, the gap-fill insulation pattern 132 may fill an inner portion of each of the plurality of word line cut regions WLC. For example, the word line cut structure CS1 may be included in a portion of the gap-fill insulation pattern 132.

Referring to FIG. 14F, a space may be provided on the vertical hole CHH by removing a portion of each of the channel layer 184 and the insulation plug 186 in a resultant material of FIG. 14E, and a conductive pad 190 filling the space may be formed.

Subsequently, a first upper insulation layer 193 on (or for example covering) the middle insulation layer 142 and the conductive pad 190 and a bit line contact pad 194 which passes through the first upper insulation layer 193 and is connected to the conductive pad 190 may be formed, a second upper insulation layer 195 on (or for example covering) the first upper insulation layer 193 and the bit line contact pad 194 may be formed, and a bit line BL which passes through the second upper insulation layer 195 and is connected to the bit line contact pad 194 may be formed.

In some embodiments, in order to form the semiconductor device 500 illustrated in FIG. 12, a wiring structure MS including a plurality of first upper wiring layers 172, a plurality of second upper wiring layers 174, and a plurality of third upper wiring layers 176, a plurality of first bonding metal pads 178A, and an interlayer insulation layer 150 filling spaces therebetween may be formed on the bit line BL. Also, the peripheral circuit structure PCS illustrated in FIG. 12 may be formed, and a plurality of bonding structures BS may be formed by bonding the plurality of first bonding metal pads 178A of the cell array structure CAS to the plurality of second bonding metal pads 178B included in the peripheral circuit structure PCS, and may thus bond the cell array structure CAS to the peripheral circuit structure PCS.

Referring again to FIG. 14F, the sacrificial substrate 810 may be removed, and the gap-fill insulation pattern 132, the ferroelectric layer 170, the channel-side dielectric layer 182, the channel layer 184, and the insulation plug 186 may be exposed by planarizing an obtained resultant material.

Referring to FIG. 14F in conjunction with FIGS. 2A to 2E, a common source line CSL on (or for example covering) surfaces exposed by the gap-fill insulation pattern 132, the ferroelectric layer 170, the channel-side dielectric layer 182, the channel layer 184, and the insulation plug 186 in a resultant material of FIG. 14F may be formed.

In embodiments, in order to manufacture the semiconductor device 500 illustrated in FIG. 12, an insulation layer 106 on (or for example covering) the common source line CSL may be formed as illustrated in FIG. 12.

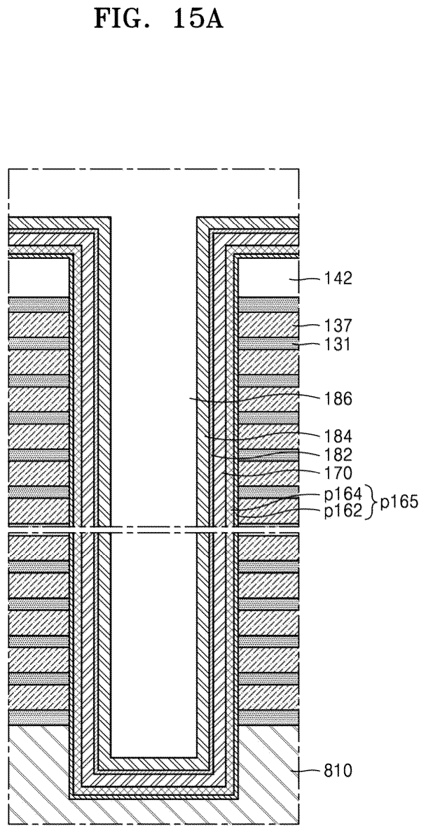

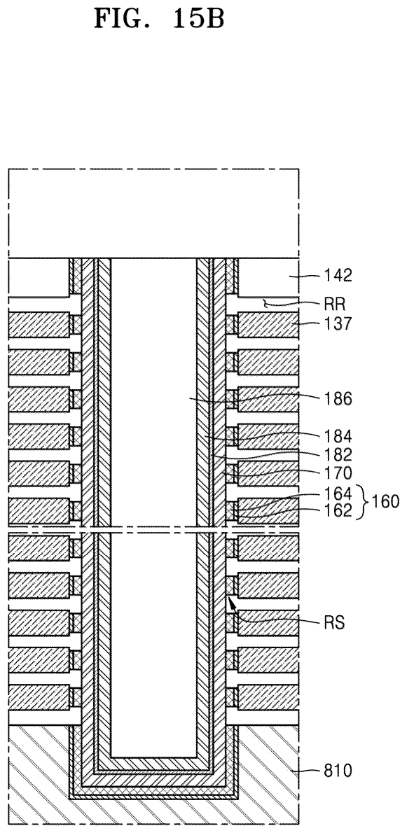

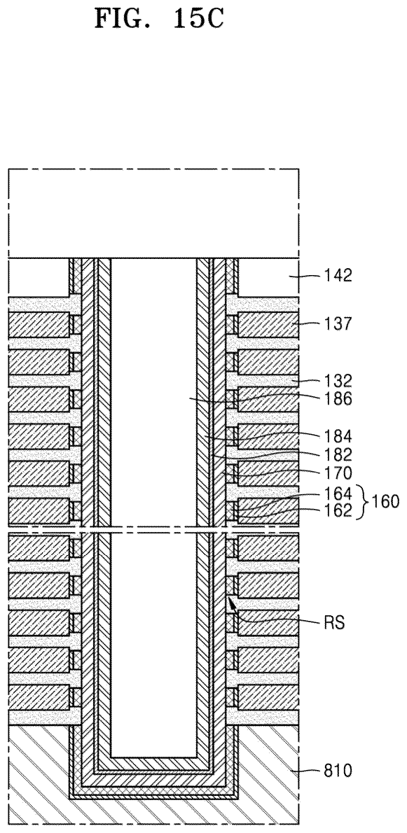

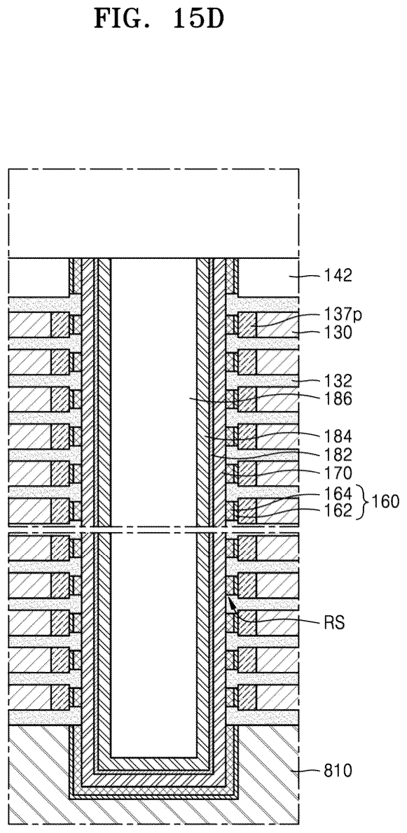

FIGS. 15A to 15D are cross-sectional views illustrating a method of manufacturing a semiconductor device, according to embodiments. In FIGS. 15A to 15D, an enlarged cross-sectional configuration, based on a process sequence, of a region corresponding to the region EXA1 of FIG. 2B is illustrated. A method of manufacturing the semiconductor device 100c illustrated in FIGS. 5A to 5C may be described with reference to FIGS. 15A to 15D. In FIGS. 15A to 15D, the same reference numerals as FIGS. 5A to 5C and 14A to 14F refer to like elements, and redundant or duplicative descriptions thereof may be omitted.

Referring to FIG. 15, similar to the description of FIG. 14A, a plurality of sacrificial insulation layers and a plurality of conductive layers may be alternatingly stacked one-by-one on a sacrificial substrate 810, and then, a middle insulation layer 142 may be formed on an uppermost sacrificial insulation layer of the plurality of sacrificial insulation layers. Subsequently, a vertical hole CHH passing through the plurality of sacrificial insulation layers, the plurality of conductive layers, and the middle insulation layer 142 and extending in the vertical direction (e.g., the Z direction) may be formed, and thus, a plurality of sacrificial insulation patterns 131 and a plurality of sacrificial conductive layers 137 each defining the vertical hole CHH may be formed. The vertical hole CHH may be formed to pass through a portion of the sacrificial substrate 810. Materials included in the sacrificial substrate 810 and the plurality of sacrificial insulation patterns 131 may be substantially as described above with reference to FIG. 14A. In some embodiments, the plurality of sacrificial conductive layers 137 may include doped polysilicon.

Subsequently, as described above with reference to FIGS. 14B and 14C, a preliminary boundary dielectric layer p165, a ferroelectric layer 170, a channel-side dielectric layer 182, and a channel layer 184 sequentially stacked on surfaces exposed at the inside and outside of the vertical hole CHH may be formed. For example, an outer wall of the boundary dielectric layer p165 may be on the plurality of sacrificial conductive layers 137. Subsequently, an insulation plug 186 filling an inner portion of the vertical hole CHH remaining on the channel layer 184 may be formed, and an upper surface of the middle insulation layer 142 may be exposed by planarizing an obtained resultant material.

Referring to FIG. 15B, a plurality of insulation spaces RR exposing an outer wall of the preliminary boundary dielectric layer p165 may be formed by removing the plurality of sacrificial insulation patterns 131 in a resultant material of FIG. 15A. After the plurality of sacrificial insulation patterns 131 are removed, a portion of an outer wall of the gate-side dielectric layer p162 may be exposed through the plurality of insulation spaces RR. The plurality of sacrificial conductive layers 137 may be apart from one another in the vertical direction (e.g., the Z direction) with one of the plurality of insulation spaces RR between two adjacent gate lines 130 of the plurality of gate lines 130.

Subsequently, a plurality of recesses RSI exposing an outer wall of the ferroelectric layer 170 may be formed by removing a portion of the gate-side dielectric layer p162 and a portion of the charge trapping layer p164 through the plurality of insulation spaces RR. According to embodiments, a plurality of boundary dielectric patterns 160 apart from one another in the vertical direction (e.g., the Z direction) may be formed by the plurality of recesses RS1. In some embodiments, a portion of a sidewall of each of the plurality of sacrificial conductive layers 137 respectively facing the plurality of boundary dielectric patterns 160 may be exposed through the plurality of first recesses RS1.

Referring again to FIG. 15C, a gap-fill insulation pattern 132 filling the plurality of insulation spaces RR and the plurality of recesses RS1 may be formed. In some embodiments, the gap-fill insulation pattern 132 may fill an inner portion of each of the plurality of word line cut regions WLC (as shown for example in FIG. 2A).

Referring to FIG. 15D, the plurality of word line cut regions WLC (as shown for example in FIG. 2A) may be again formed in a resultant material of FIG. 14C, and then, a plurality of conductive patterns 137p may be formed by removing a portion of each of the plurality of sacrificial conductive layers 137 through the plurality of word line cut regions WLC.

Subsequently, a space formed by removing the plurality of sacrificial conductive layers 137 may be filled by the plurality of gate lines 130. Subsequently, as illustrated in FIG. 2A, an inner portion of each of the plurality of word line cut regions WLC may be filled with a word line cut structure CS1.

Subsequently, as described above with reference to FIG. 14F, a conductive pad 190 filling a space on the vertical hole CHH of FIG. 15D, a first upper insulation layer 193 on (or for example covering) the middle insulation layer 142 and the conductive pad 190, and a bit line contact pad 194 which passes through the first upper insulation layer 193 and is connected to the conductive pad 190 may be formed, and a second upper insulation layer 195 on (or for example covering) the first upper insulation layer 193 and the bit line contact pad 194, and a bit line BL which passes through the second upper insulation layer 195 and is connected to the bit line contact pad 194 may be formed.

Subsequently, the sacrificial substrate 810 may be removed, and the gap-fill insulation pattern 132, the ferroelectric layer 170, the channel-side dielectric layer 182, the channel layer 184, and the insulation plug 186 may be exposed by planarizing an obtained resultant material. Subsequently, the semiconductor device 100c described above with reference to FIGS. 5A to 5C may be formed by forming the common source line CSL on (or for example covering) exposed surfaces of the gap-fill insulation pattern 132, the ferroelectric layer 170, the channel-side dielectric layer 182, the channel layer 184, and the insulation plug 186.

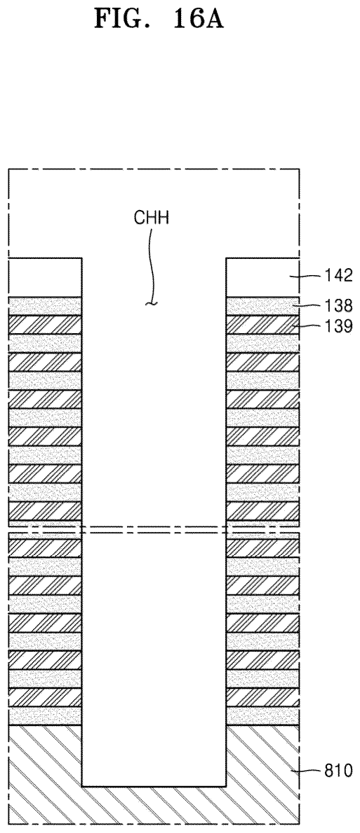

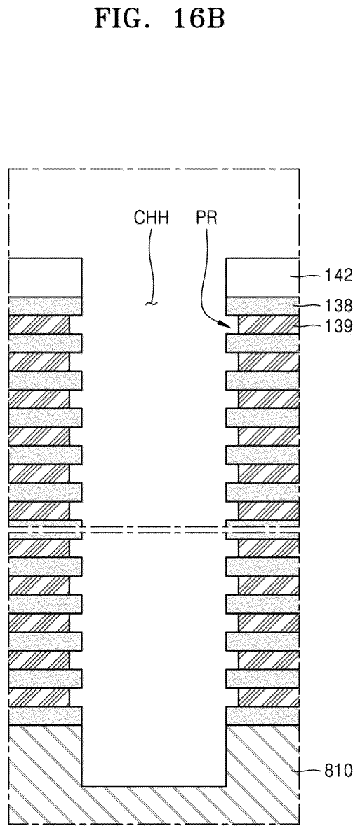

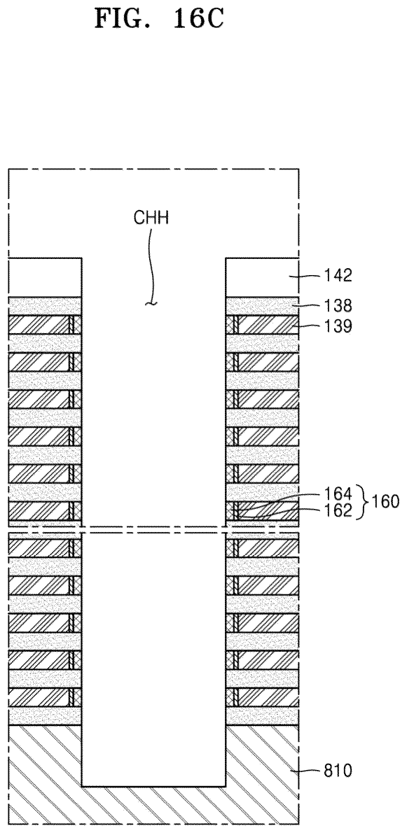

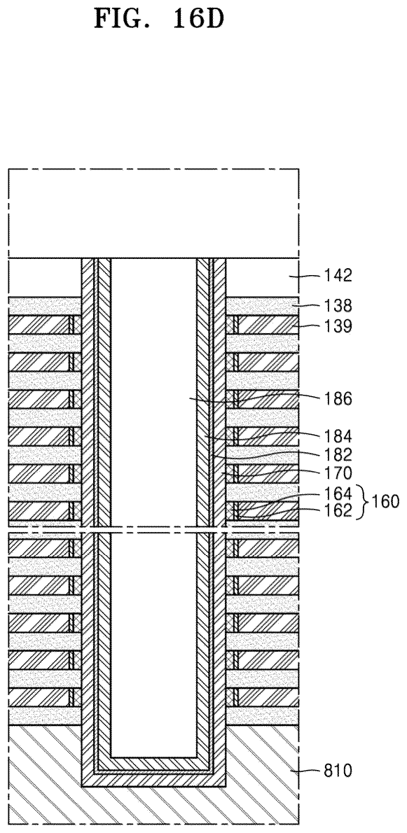

FIGS. 16A to 16D are cross-sectional views illustrating a method of manufacturing a semiconductor device, according to embodiments. In FIGS. 16A to 16D, an enlarged cross-sectional configuration, based on a process sequence, of a region corresponding to the region EXA1 of FIG. 2B is illustrated. A method of manufacturing the semiconductor device 100h illustrated in FIG. 10 may be described with reference to FIGS. 16A to 16D. In FIGS. 16A to 16D, the same reference numerals as FIGS. 2A to 2E, 10, and 14A to 14F refer to like elements, and redundant or duplicative descriptions thereof may be omitted.

Referring to FIG. 16A, a plurality of insulation layers and a plurality of sacrificial insulation layers may be alternatingly stacked one-by-one on a sacrificial substrate 810, and then, a middle insulation layer 142 may be formed on an uppermost sacrificial insulation layer of the plurality of sacrificial insulation layers. Subsequently, a vertical hole CHH passing through the a plurality of insulation layers, the plurality of sacrificial insulation layers, and the middle insulation layer 142 and extending in the vertical direction (e.g., the Z direction) may be formed, and thus, a plurality of insulation patterns 138 and a plurality of sacrificial patterns 139 each defining the vertical hole CHH may be formed. The vertical hole CHH may be formed to pass through a portion of the sacrificial substrate 810.

The sacrificial substrate 810 may include silicon. The plurality of insulation patterns 138 may include silicon oxide, and the plurality of sacrificial patterns 139 may include silicon nitride. Each of the plurality of sacrificial patterns 139 may secure a space for forming a gate stack GS (as shown for example in FIGS. 2A and 2E) in a post-processing operation.

Referring to FIG. 16B, a plurality of pattern spaces PR may be formed by removing partial portions of the plurality of sacrificial patterns 139 exposed through the vertical hole CHH in a resultant material of FIG. 16A. For example, the plurality of pattern spaces PR may vertically overlap the plurality of sacrificial patterns 139.

In some embodiments, a dry etching process, a wet etching process, or a combination thereof may be used to form the plurality of pattern spaces PR.

Referring to FIG. 16C, a plurality of boundary dielectric patterns 160 respectively filling the plurality of pattern spaces PR may be formed. In some embodiments, in order to form the plurality of boundary dielectric patterns 160, a first dielectric layer filling the plurality of pattern spaces PR and a portion of the vertical hole CHH may be formed, and then, a plurality of gate-side dielectric patterns 162 partially filling the plurality of pattern spaces PR through lateral-direction etching and on (or for example covering) sidewalls of the plurality of sacrificial patterns 139 may be formed. Subsequently, a second dielectric layer filling a remaining portion of the plurality of pattern spaces PR and a portion of the vertical hole CHH may be formed, and then, a plurality of charge trapping patterns 164 may be formed by again forming the vertical hole CHH exposing the plurality of insulation patterns 138. In some embodiments, an ALD process may be performed for forming the first dielectric layer and the second dielectric layer.

Referring to FIG. 16D, in a resultant material of FIG. 16C, a ferroelectric layer 170 on (or for example covering) an inner wall of the vertical hole CHH and an upper surface of the middle insulation layer 142 may be formed, and then, a channel-side dielectric layer 182 filling a portion of the vertical hole CHH on the ferroelectric layer 170 and a channel layer 184 filling a portion of the vertical hole CHH on the channel-side dielectric layer 182 may be formed. For example, an outer wall of the ferroelectric layer 170 may be on the plurality of boundary dielectric patterns 160 and the plurality of insulation patterns 138. Subsequently, an insulation plug 186 filling an inner portion of the vertical hole CHH remaining on the channel layer 184 may be formed, and an upper surface of the middle insulation layer 142 may be exposed by planarizing an obtained resultant material.

Subsequently, in a resultant material of FIG. 16D, a plurality of gate spaces may be formed by removing the plurality of sacrificial patterns 139. To form the plurality of gate spaces, the plurality of word line cut regions WLC described above with reference to FIG. 2A may be previously formed, and the plurality of sacrificial patterns 139 may be removed through the plurality of word line cut regions WLC. After the plurality of sacrificial patterns 139 are removed, outer walls of the plurality of boundary dielectric patterns 160 may be exposed through the plurality of gate spaces. Subsequently, the plurality of gate spaces may be filled with the plurality of gate lines 130. Subsequently, as illustrated in FIG. 2A, an inner portion of each of the plurality of word line cut regions WLC may be filled with a word line cut structure CS1.

Subsequently, as described above with reference to FIG. 14F, a space may be provided on the vertical hole CHH by removing a portion of each of the channel layer 166 and the insulation plug 168, and a conductive pad 190 filling the space may be formed, and then, the first upper insulation layer 193, the bit line contact pad 194, the second upper insulation layer 195, and the bit line BL may be formed.

Subsequently, the sacrificial substrate 810 may be removed, and the gap-fill insulation pattern 132, the ferroelectric layer 170, the channel-side dielectric layer 182, the channel layer 184, and the insulation plug 186 may be exposed by planarizing an obtained resultant material, and then, the semiconductor device 100h described above with reference to FIG. 10 may be formed by forming the common source line CSL on (or for example covering) exposed surfaces of the gap-fill insulation pattern 132, the ferroelectric layer 170, the channel-side dielectric layer 182, the channel layer 184, and the insulation plug 186.

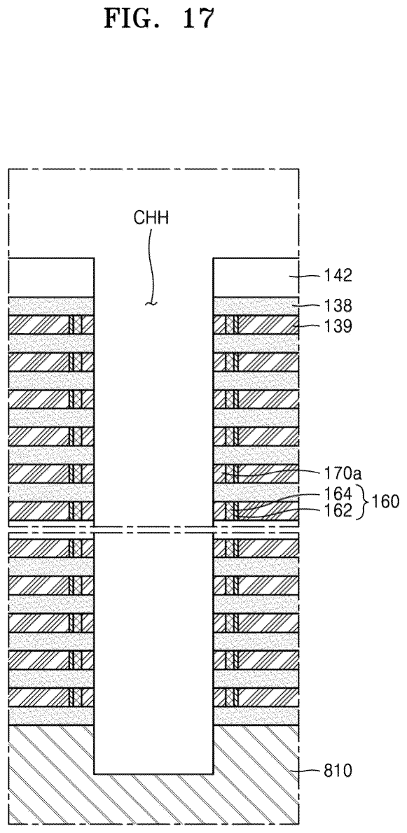

FIG. 17 is a cross-sectional view illustrating a method of manufacturing a semiconductor device, according to embodiments. In FIG. 17, an enlarged cross-sectional configuration, based on a process sequence, of a region corresponding to the region EXA1 of FIG. 2B is illustrated. A method of manufacturing the semiconductor device 100i illustrated in FIG. 11 may be described with reference to FIG. 17. In FIG. 17, the same reference numerals as FIGS. 6A, 6B, 11, and 16A to 16D refer to like elements, and redundant or duplicative descriptions thereof may be omitted.

Referring to FIG. 17, the processes described above with reference to FIGS. 16A and 16B may be performed. Subsequently, a plurality of boundary dielectric patterns 160 and a plurality of ferroelectric patterns 170a each filling the plurality of pattern spaces PR may be formed. In some embodiments, in order to form the plurality of boundary dielectric patterns 160 and the plurality of ferroelectric patterns 170a, a first dielectric layer filling the plurality of pattern spaces PR and a portion of the vertical hole CHH may be formed, and then, a plurality of gate-side dielectric patterns 162 partially filling the plurality of pattern spaces PR through lateral-direction etching and on (or for example covering) sidewalls of the plurality of sacrificial patterns 139 may be formed. Subsequently, a second dielectric layer filling a portion of each of the plurality of pattern spaces PR and a portion of the vertical hole CHH may be formed, and then, a plurality of charge trapping patterns 164 partially filling the plurality of pattern spaces PR and on (or for example covering) each of inner walls of the plurality of gate-side dielectric patterns 162 may be formed through lateral-direction etching. Subsequently, a third dielectric layer filling a remaining portion of the plurality of pattern spaces PR and a portion of the vertical hole CHH may be formed, and then, a plurality of ferroelectric patterns 170a may be formed by again forming the vertical hole CHH exposing the plurality of insulation patterns 138.

Subsequently, a channel-side dielectric layer 182 on (or for example covering) an inner wall of the vertical hole CHH and an upper surface of the middle insulation layer 142 and a channel layer 184 filling a portion of the vertical hole CHH on the channel-side dielectric layer 182 may be formed, and an insulation plug 186 filling an inner portion of the vertical hole CHH remaining on the channel layer 184 may be formed, and then, an upper surface of the middle insulation layer 142 may be exposed by planarizing an obtained resultant material.

Subsequently, the semiconductor device 100i illustrated in FIG. 11 may be manufactured by performing the processes described above with reference to FIG. 16D.

Hereinabove, the methods of manufacturing the semiconductor device 100 illustrated in FIGS. 2A to 2E, the semiconductor device 100c illustrated in FIGS. 5A to 5C, the semiconductor device 100h illustrated in FIG. 10, and the semiconductor device 100i illustrated in FIG. 11 have been described with reference to FIGS. 14A to 17, and by implementing various modifications and changes within the scope of the disclosure, embodiments may be provided so that this disclosure will be thorough and complete and will fully convey the scope of the disclosure to those of ordinary skill in the art. The following embodiments may be modified in various ways, and the scope of the disclosure is not limited to the following embodiments.

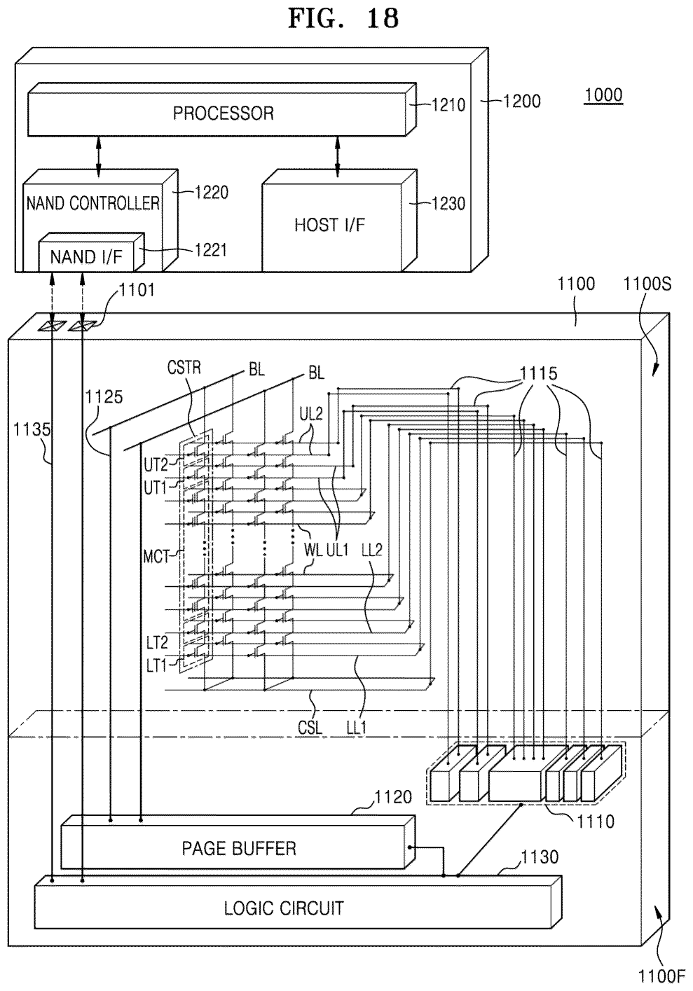

FIG. 18 is a diagram schematically illustrating an electronic system 1000 including a semiconductor device, according to an embodiment.

Referring to FIG. 18, the electronic system 1000 according to an embodiment may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device, a universal serial bus (USB), a computing system, a medical device, or a communication device, which includes at least one semiconductor device 1100.

The semiconductor device 1100 may be a non-volatile memory device. For example, the semiconductor device 1100 may be a NAND flash memory device including at least one of the structures of the semiconductor devices 100, 100a, 100b, 100c, 100d, 100e, 100f, 100g, 100h, 100i, 500, and 600 described above with reference to FIGS. 2A to 13. The semiconductor device 1100 may include a first structure 1100F and a second structure 1100S on the first structure 1100F. In embodiments, the first structure 1100F may be disposed next to the second structure 1100S. The first structure 1100F may be a peripheral circuit structure which includes a decoder circuit 1110, a page buffer 1120, and a logic circuit 1130. The second structure 1100S may be a memory cell structure which includes a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to embodiments.

In embodiments, the upper transistors UT1 and UT2 may include a string selection transistor, and the lower transistors LT1 and LT2 may include a ground selection transistor. A plurality of gate lower lines LL1 and LL2 may respectively be gate electrodes of the lower transistors LT1 and LT2. The word line WL may be a gate electrode of the memory cell transistor MCT, and the gate upper lines UL1 and UL2 may respectively be gate electrodes of the upper transistors UT1 and UT2.

The common source line CSL, the plurality of gate lower lines LL1 and LL2, the plurality of word lines WL, and a plurality of gate upper lines UL1 and UL2 may be electrically connected to the decoder circuit 1110 through a plurality of first connection wirings 1115 extending up to the second structure 1100S from an inner portion of the first structure 1100F. A plurality of bit lines BL may be electrically connected to the page buffer 1120 through a plurality of second connection wirings 1125 extending up to the second structure 1100S from the inner portion of the first structure 1100F.

In the first structure 1100F, the decoder circuit 1110 and the page buffer 1120 may execute a control operation on at least one of the plurality of memory cell transistors MCT. The decoder circuit 1110 and the page buffer 1120 may be controlled by the logic circuit 1130.

The semiconductor device 1100 may communicate with a controller 1200 through an I/O pad 1101 electrically connected to the logic circuit 1130. The I/O pad 1101 may be electrically connected to the logic circuit 1130 through an I/O connection wiring 1135 extending up to the second structure 1100S from the inner portion of the first structure 1100F.

The controller 1200 may include a processor 1210, a NAND controller 1220, and a host interface 1230. According to embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate based on certain firmware and may control the NAND controller 1220 to access the semiconductor device 1100. The NAND controller 1220 may include a NAND interface 1221 which processes communication with the semiconductor device 1100. A control command for controlling the semiconductor device 1100, data to be stored in the plurality of memory cell transistors MCT of the semiconductor device 1100, and data to be read from the plurality of memory cell transistors MCT of the semiconductor device 1100 may be transferred through the NAND interface 1221. The host interface 1230 may provide a communication function between the electronic system 1000 and an external host. When the control command is received from the external host through the host interface 1230, the processor 1210 may control the semiconductor device 1100 based on the control command.

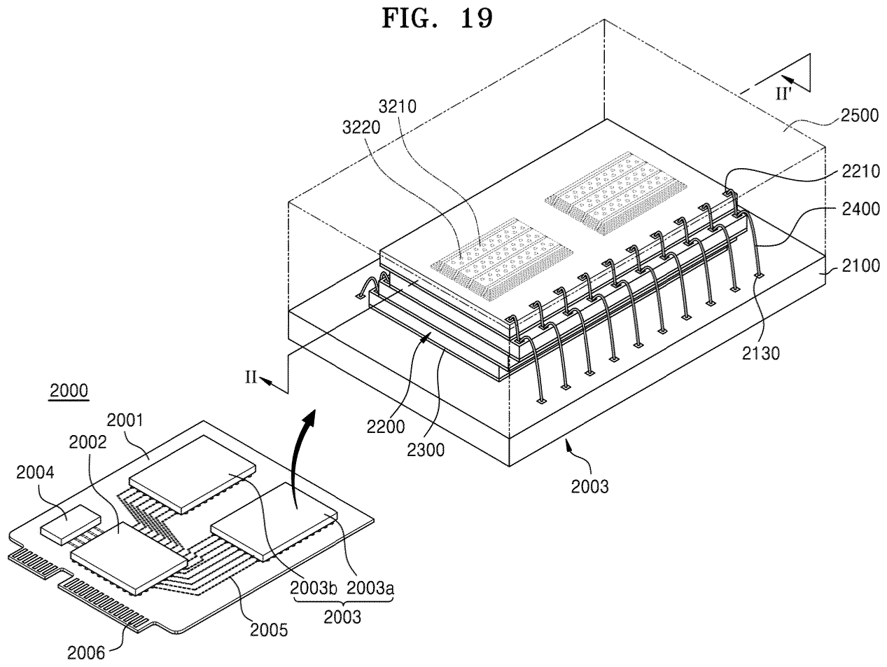

FIG. 19 is a diagram schematically illustrating an electronic system 2000 including a semiconductor device, according to an embodiment.

Referring to FIG. 19, the electronic system 2000 according to an embodiment may include a main substrate 2001, a controller 2002 mounted on the main substrate 2001, one or more semiconductor packages 2003, and dynamic random access memory (DRAM) 2004. The semiconductor package 2003 and the DRAM 2004 may be connected to the controller 2002 by a plurality of wiring patterns 2005 formed in the main substrate 2001.

The main substrate 2001 may include a connector 2006 including a plurality of pins coupled to the external host. The number and arrangement of pins in the connector 2006 may be changed based on a communication interface between the electronic system 2000 and the external host. In embodiments, the electronic system 2000 may communicate with the external host, based on one of interfaces such as USB, peripheral component interconnect express (PCI-E), serial advanced technology attachment (SATA), and M-Phy for universal flash storage (UFS). In embodiments, the electronic system 2000 may operate with power supplied from the external host through the connector 2006. The electronic system 2000 may further include a power management integrated circuit (PMIC) which distributes power, supplied from the external host, to the controller 2002 and the semiconductor package 2003.

The controller 2002 may write data in the semiconductor package 2003, or may read data from the semiconductor package 2003, and may improve an operation speed of the electronic system 2000.

The DRAM 2004 may be a buffer memory for decreasing a speed difference between the external host and the semiconductor package 2003 which may be a data storage space. The DRAM 2004 included in the electronic system 2000 may operate as a certain cache memory and may provide a space for temporarily storing data in a control operation on the semiconductor package 2003. When the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 on the package substrate 2100, an adhesive layer 2300 disposed on a lower surface of each of the plurality of semiconductor chips 2200, a connection structure 2400 electrically connecting the plurality of semiconductor chips 2200 to the package substrate 2100, and a molding layer 2500 on (or for example covering) the plurality of semiconductor chips 2200 and the connection structure 2400 on the package substrate 2100.

The package substrate 2100 may be a printed circuit board (PCB) including a plurality of package upper pads 2130. Each of the plurality of semiconductor chips 2200 may include an I/O pad 2210. The I/O pad 2210 may correspond to the I/O pad 1101 of FIG. 18. Each of the plurality of semiconductor chips 2200 may include a plurality of gate stacks 3210 and a plurality of channel structures 3220. Each of the plurality of semiconductor chips 2200 may include at least one of the structures of the semiconductor devices 100, 100a, 100b, 100c, 100d, 100e, 100f, 100g, 100h, 100i, 500, and 600 described above with reference to FIGS. 2A to 13.

In embodiments, the connection structure 2400 may be a bonding wire which electrically connects the I/O pad 2210 to the package upper pad 2130. Therefore, in the first and second semiconductor packages 2003a and 2003b, the plurality of semiconductor chips 2200 may be electrically connected to each other by a bonding wire scheme and may be electrically connected to the package upper pad 2130 of the package substrate 2100. In embodiments, in the first and second semiconductor packages 2003a and 2003b, the plurality of semiconductor chips 2200 may be electrically connected to each other by a connection structure including a through silicon via (TSV), instead of the connection structure 2400 based on the bonding wire scheme.

In embodiments, the controller 2002 and the plurality of semiconductor chips 2200 may be included in one package. In embodiments, the controller 2002 and the plurality of semiconductor chips 2200 may be mounted on a separate interposer substrate which differs from the main substrate 2001, and the controller 2002 and the plurality of semiconductor chips 2200 may be connected to each other by a wiring formed in the interposer substrate.

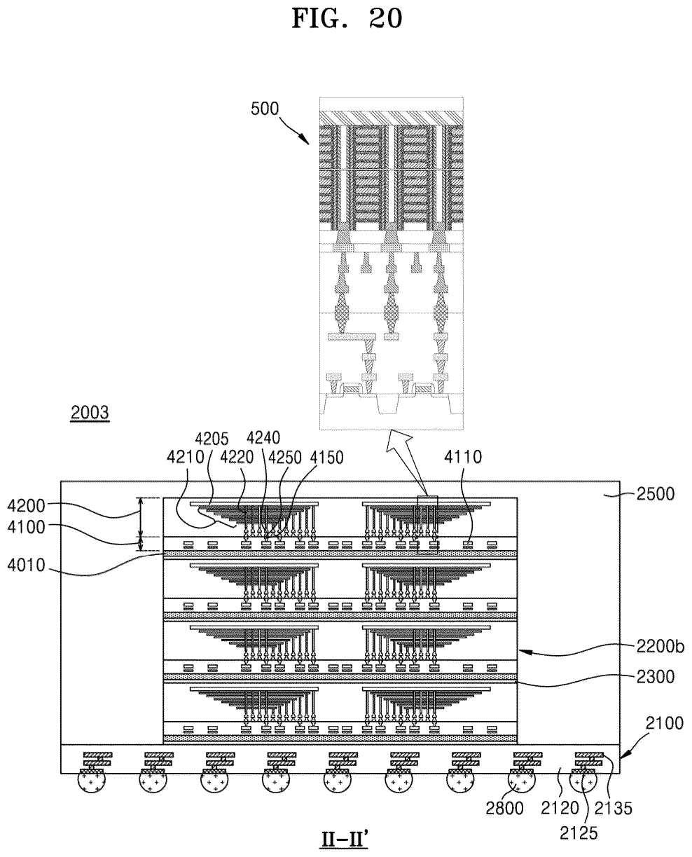

FIG. 20 is a cross-sectional view schematically illustrating semiconductor packages 2003 according to an embodiment. In FIG. 20, a cross-sectional configuration taken along line II-II′ of FIG. 19 is illustrated in more detail.

Referring to FIG. 20, the semiconductor package 2003, each of a plurality of semiconductor chips 2200b may include a semiconductor substrate 4010, a first structure 4100 on the semiconductor substrate 4010, and a second structure 4200 bonded to the first structure 4100 by a wafer bonding scheme on the first structure 4100.

The first structure 4100 may include a peripheral circuit region including peripheral wirings 4110 and first bonding structures 4150. The second structure 4200 may include a common source line 4205, a gate stack structure 4210 between the common source line 4205 and the first structure 4100, memory channel structures 4220 passing through the gate stack structure 4210, and second bonding structures 4250 electrically connected to the memory channel structures 4220 and word lines (e.g., the word lines WL of FIG. 18) of the gate stack structure 4210. For example, the second bonding structures 4250 may be electrically connected to the memory channel structures 4220 and the word lines (e.g., the word lines WL of FIG. 18) through gate connection wirings electrically connected to the word lines (e.g., the word lines WL of FIG. 18) and bit lines 4240 electrically connected to the memory channel structure 4220. The first bonding structures 4150 of the first structure 4100 may be on and be bonded to the second bonding structures 4250 of the second structure 4200. Portions where the first bonding structures 4150 are bonded to the second bonding structures 4250 may include, for example, copper (Cu).

Each of the plurality of semiconductor chips 2200b may further include an I/O pad (e.g., the I/O pad 2210 of FIG. 9) electrically connected to the peripheral wirings 4110 of the first structure 4100.

The plurality of semiconductor chips 2200 of FIG. 19 and the plurality of semiconductor chips 2200b of FIG. 20 may be electrically connected to each other by the plurality of connection structures 2400 based on a bonding wire type. Furthermore, in embodiments, semiconductor chips such as the plurality of semiconductor chips 2200 of FIG. 19 and the plurality of semiconductor chips 2200b of FIG. 20 in one semiconductor package may be electrically connected to each other by a connection structure including a TSV.

Hereinabove, exemplary embodiments have been described in the drawings and the specification. Some embodiments have been described by using the terms described herein, but this has been merely used for providing examples, and has not been used for limiting a meaning or limiting the scope of the disclosure defined in the following claims. Therefore, it may be understood by those of ordinary skill in the art that various modifications and other equivalent embodiments may be implemented without departing from the scope of the disclosure. Accordingly, the spirit and scope of the disclosure may be defined based on the spirit and scope of the following claims.

While some embodiments of the disclosure have been particularly shown and described, it will be understood that various changes in form and details may be made therein without departing from the spirit and scope of the following claims.

What is claimed is:

1. A semiconductor device comprising:
a plurality of gate lines which are spaced apart in a vertical direction, and which are around a vertical hole;
a channel layer extending in the vertical hole;
a composite dielectric layer disposed between the plurality of gate lines and the channel layer, wherein the composite dielectric layer comprises a channel-side dielectric layer, a ferroelectric layer, and a boundary dielectric layer sequentially stacked in a direction toward the plurality of gate lines from the channel layer; and
a gap-fill insulation pattern disposed between the plurality of gate lines,
wherein the boundary dielectric layer comprises a plurality of boundary dielectric patterns which are spaced apart in the vertical direction and which face the plurality of gate lines, and
wherein a first height corresponding to a length of each boundary dielectric pattern of the plurality of boundary dielectric patterns in the vertical direction is less than a second height corresponding to a length of each gate line of the plurality of gate lines in the vertical direction.

2. The semiconductor device of claim 1, wherein the each boundary dielectric pattern comprises:
a charge trapping pattern on the ferroelectric layer; and
a gate-side dielectric pattern on a corresponding gate line from among the plurality of gate lines.

3. The semiconductor device of claim 2, wherein the charge trapping pattern and the gate-side dielectric pattern are on the gap-fill insulation pattern.

4. The semiconductor device of claim 1, wherein the each boundary dielectric pattern comprises a curved surface facing the gap-fill insulation pattern.

5. The semiconductor device of claim 1, wherein the first height increases progressively toward the ferroelectric layer.

6. The semiconductor device of claim 1, wherein the channel-side dielectric layer is on an outer wall of the channel layer and extends in the vertical direction, and
wherein the ferroelectric layer is on an outer wall of the channel-side dielectric layer and extends in the vertical direction.

7. The semiconductor device of claim 1, wherein the ferroelectric layer comprises a plurality of ferroelectric patterns which are spaced apart in the vertical direction and which face the plurality of boundary dielectric patterns.

8. The semiconductor device of claim 1, wherein the ferroelectric layer comprises a plurality of ferroelectric patterns which are spaced apart in the vertical direction and which face the plurality of boundary dielectric patterns, and
wherein the channel-side dielectric layer comprises a plurality of channel-side dielectric patterns which are spaced apart in the vertical direction and which face the plurality of ferroelectric patterns.

9. The semiconductor device of claim 1, further comprising a plurality of conductive patterns which are separated in the vertical direction,
wherein each conductive pattern from among the plurality of conductive patterns is disposed between a corresponding gate line from among the plurality of gate lines and a corresponding boundary dielectric pattern from among the plurality of boundary dielectric patterns.

10. The semiconductor device of claim 1, wherein the gap-fill insulation pattern comprises an air gap which vertically overlaps the plurality of gate lines at least partially.

11. A semiconductor device comprising:
a stack structure comprising a plurality of gate lines spaced apart in a vertical direction and overlapping in the vertical direction, and a gap-fill insulation pattern between the plurality of gate lines;
a channel layer extending in a vertical hole which passes through the stack structure in the vertical direction;
a channel-side dielectric layer on an outer wall of the channel layer; and
a plurality of ferroelectric patterns spaced apart in the vertical direction and overlapping in the vertical direction, wherein the gap-fill insulation pattern is between each ferroelectric pattern of the plurality of ferroelectric patterns, and wherein the each ferroelectric pattern is between a corresponding pair of adjacent gate lines from among the plurality of gate lines,
wherein a portion of a sidewall of each gate line from among the plurality of gate lines facing the channel layer is on the gap-fill insulation pattern.

12. The semiconductor device of claim 11,
wherein the gap-fill insulation pattern comprises:
a plurality of first portions overlapping the plurality of gate lines in the vertical direction; and
a plurality of second portions extending from the plurality of first portions and overlapping the plurality of ferroelectric patterns in the vertical direction, and
wherein at least some of each second portion from among the plurality of second portions is longer in the vertical direction than a corresponding first portion from among the plurality of first portions.

13. The semiconductor device of claim 11, wherein each ferroelectric pattern from among the plurality of ferroelectric patterns comprises a curved surface facing the gap-fill insulation pattern.

14. The semiconductor device of claim 11, further comprising a plurality of boundary dielectric patterns, wherein each boundary dielectric pattern is between a corresponding gate line from among the plurality of gate lines and a corresponding ferroelectric pattern from among the plurality of ferroelectric patterns,
wherein the each boundary dielectric pattern comprises:
a charge trapping pattern the corresponding ferroelectric pattern; and
a gate-side dielectric pattern on the corresponding gate line.

15. The semiconductor device of claim 14, wherein the charge trapping pattern and the gate-side dielectric pattern are on the gap-fill insulation pattern.

16. The semiconductor device of claim 11, wherein the channel-side dielectric layer comprises a plurality of channel-side dielectric patterns spaced apart in the vertical direction, wherein each channel-side dielectric pattern from among the plurality of channel-side dielectric patterns is between the channel layer and a corresponding ferroelectric pattern from among the plurality of ferroelectric patterns, and
wherein a portion of the gap-fill insulation pattern is on an outer wall of the channel layer between the plurality of channel-side dielectric patterns.

17. A semiconductor device comprising:
a plurality of gate lines spaced apart in a vertical direction around a vertical hole;
a channel layer extending in the vertical hole;
a channel-side dielectric layer on an outer wall of the channel layer and extending in the vertical direction;
a ferroelectric layer extending in the vertical direction between the channel-side dielectric layer and the plurality of gate lines;
a plurality of charge trapping patterns spaced apart in the vertical direction, wherein each charge trapping pattern from among the plurality of charge trapping patterns is between the ferroelectric layer and a corresponding gate line from among the plurality of gate lines;
a plurality of gate-side dielectric patterns separated in the vertical direction, wherein each gate-side dielectric pattern from among the plurality of gate-side dielectric patterns is between a corresponding charge trapping pattern from among the plurality of charge trapping patterns and the corresponding gate line; and
a gap-fill insulation pattern comprising a plurality of first portions and a plurality of second portions, wherein each first portion from among the plurality of first portions is between a corresponding pair of adjacent gate lines from among the plurality of gate lines, and wherein the plurality of second portions extend from the plurality of first portions and are on the ferroelectric layer,
wherein the plurality of second portions vertically overlap the plurality of charge trapping patterns and the plurality of gate-side dielectric patterns,
wherein at least some of each second portion from among the plurality of second portions is longer than a corresponding first portion of the plurality of first portions in the vertical direction, and
wherein a portion of a sidewall, facing the channel layer, of each gate line of the plurality of gate lines comprises a portion of the gap-fill insulation pattern facing a corresponding second portion of the plurality of second portions in a horizontal direction.

18. The semiconductor device of claim 17, wherein a length in the vertical direction of each gate-side dielectric pattern from among the plurality of gate-side dielectric patterns is less than a length in the vertical direction of each gate line of the plurality of gate lines.

19. The semiconductor device of claim 17, wherein the plurality of charge trapping patterns and the plurality of gate-side dielectric patterns comprise a curved surface on the gap-fill insulation pattern.

20. The semiconductor device of claim 17. wherein the gap-fill insulation pattern comprises an air gap.
